(19) United States
(12) Patent Application Publication
(10) Pub. No.: US 2022/0093884 A1
(43) Pub. Date: Mar. 24, 2022

(54) ORGANIC SINGLE-CRYSTALLINE SEMICONDUCTOR STRUCTURE AND PREPARATION METHOD THEREOF

(71) Applicant: ZHEJIANG UNIVERSITY, Hangzhou (CN)

(72) Inventors: Hanying Li, Hangzhou (CN); Ruihan Wu, Hangzhou (CN)

(21) Appl. No.: 17/358,024

(22) Filed: Jun. 25, 2021

Related U.S. Application Data
(63) Continuation of application No. PCT/CN2020/112727, filed on Aug. 31, 2020.

(30) Foreign Application Priority Data
Aug. 29, 2019 (CN) 201910810780.9
Nov. 3, 2019 (CN) 201911062819.X
Mar. 12, 2020 (CN) 202010172053.7

(51) Int. Cl. H01L 51/05; H01L 51/00

(52) U.S. Cl. CPC H01L 51/0541; H01L 51/0007; H01L 51/0545

(57) ABSTRACT

An organic single-crystalline semiconductor structure is provided. The organic single-crystalline semiconductor structure composes substrate, growth-assisted layer, electrodes, organic single-crystalline semiconductor layer. The growth-assisted layer deposited on the substrate from bottom to top. The organic single-crystalline semiconductor layer is defined as the organic semiconductor single-crystal thin film which basically maintained its original morphology after crossing the electrodes. The organic single-crystalline semiconductor thin film could realize full-covering over the arbitrary-shaped or arbitrary-sized bottom-contacted substrates, and the nearly ideal morphology on industrialized scale could be achieved. This organic single-crystalline semiconductor structure could be applied as key part in organic field-effect transistor, in order to realized fast transportation of charge carriers. A facially manufactured and high performance organic field-effect transistor device is also provided, with good potential in the fields of organic electronics and optoelectronics.

### CROSS REFERENCE TO RELATED APPLICATIONS

This application is a continuation of PCT Patent Application No. PCT/CN2020/112727, filed on Aug. 31, 2020, entitled “ORGANIC SINGLE-CRYSTALLINE SEMICONDUCTOR STRUCTURE AND PREPARATION METHOD THEREOF”, which claims foreign priority of Chinese Patent Applications Nos. 201910810780.9 filed Aug. 29, 2019; 201911062819.X, filed Nov. 3, 2019; 202010172053.7, filed Mar. 12, 2020 in the China National Intellectual Property Administration (CNIPA), the entire contents of which are hereby incorporated by reference in their entireties.

### TECHNICAL FIELD

The disclosure relates to the technical field of organic semiconductors, and particularly relates to an organic single-crystalline semiconductor structure and preparation method thereof.

### BACKGROUND

In the field of semiconductor devices, organic semiconductor devices have drawn attention in a wide range due to the lightweight, flexibility, as well as potential of mass production. Enormous new techniques have dramatically increased the development of organic optoelectronic devices including organic photovoltaics (OPVs), organic light-emitting diodes (OLEDs), and organic field-effect transistors (OFETs). The device structure is one of the keys to realize high-performance optoelectronic functions. For instance, the structure of OFET mainly comprises: (i) electrodes, which could be classified to source, drain and gate according to the different function; (ii) organic semiconductor layer; which is the most essential part as active layer; (iii) dielectric layer/insulating layer.

Currently, BGTC (BGTC, FIG. 1A), Bottom Gate-Bottom Contact (BGBC, FIG. 1B), and TGBC (TGBC, FIG. 1C) are common device configurations used for OFETs (J. Zaumseil et al., Chemical Reviews, 107, 4, 1296(2007)). The major differences are on the basis of the relative position to each other among source/drain electrodes, organic semiconductor layer and gate electrodes. The source and drain electrodes are usually located at the same side relative to the organic semiconductor layer, thus the source/drain electrodes are used as a general term for the source electrode and the drain electrode.

According to the working principle of OFETs, charge carriers are injected from the source and extracted by drain. The charge accumulation zone are formed at the interface between the organic semiconductor layer and the dielectric layer to construct the conduction pathways. As illustrated in FIG. 2 (A. Fischer et al., Physics Review Applied 8, 054012(2017)), the source/drain electrodes of the coplanar devices (e.g. BGBC) are located at the same side with dielectric layer in relation to organic semiconductor layer. In this situation, the injection of charge carriers occurs at the contact edges between the source and the organic semiconductor layer. Moreover, depletion regions are formed between the contact edges and conduction pathways formed by the accumulated charges. The effective transport length of charge carriers is reduced, and it becomes to a bottleneck for charge carriers' injection and extraction.

With respect to staggered devices including BGTC and TGBC, all the contact area (which is between source/drain electrodes and organic semiconductor layer) facing the gate electrodes can be involved in the injection and extraction of charge carriers; the current is not 0; moreover, better device performance could be achieved with a larger the injection area from the source electrodes, reduced contact resistances, as well as larger active regions. In particular, during the fabrication process of BGTC devices (FIG. 1A), the semiconductor layer is deposited on the gate dielectric, and source/drain electrodes are deposited at last. This device architecture is widely used in organic semiconductor thin-film field-effect transistors. However, the thermal damage on the organic semiconductor layer are inevitable when depositing source/drain electrodes. The thermal damage refers to a reduced output current which is induced by non-uniformly distributed density of trap states around the source/drain electrodes. Furthermore, metal atoms especially Au or Ag might penetrate into the organic semiconductor thin-film to change the barrier at the electrode/semiconductor contact interface, resulting in great affection on the injection of charge carriers. Moreover, since the organic semiconductor layer of BGTC devices is directly exposed to the air, the device lifetime is easily affected by the environment, therefore the stability problems of device should be considered.

In TGBC devices (FIG. 1C), the organic semiconductor layer is located on the top of source/drain electrodes. Due to the gravity force, the contact area between organic semiconductor layer and source/drain electrodes are larger than that in Top Contact devices, which is better for realizing efficient injection of charge carriers. The electrical performance of organic semiconductor devices is also restricted by resistance, contact resistance problems are considered to limit the transit frequencies for OFETs. Higher contact resistance requires higher voltage for device operation, and it also lead to thermal instability of devices. Especially for short-channel devices in integrated circuits, the ratio of depletion region under source/drain electrodes to the entire channel gets larger with shorter channel, and it also contributes a larger ratio of contact resistance to the total resistance, eventually the device performance could be severely hampered. To lower the contact resistance, suppressing the contribution of metal/organic interface resistance (Rᵢₙₜ) and access resistance (R_{access}) is wildly adopted. It has been reported that contact resistance could be significantly reduced by introducing appropriate dopant layer between source/drain electrodes and organic semiconductor layer and adopting TGBC configuration instead of BGTC, respectively. (P. Darmawan et al., Advanced Functional Materials, 22, 4577 (2012)) As it showed in FIG. 3, the total resistance of BGTC devices is consist of Rᵢₙₜ, R_{access} and channel resistance (R_{channel}). As for TGBC devices, due to the overlapping organic layer on top of the source/drain electrodes, the access region (for charge-transport process in the bulk of the semiconductor from the contact to the channel) has been reduced, thus the total resistance only consists of Rᵢₙₜ and R_{channel}, and the limit of R_{access} steamed from thickness of bulk organic semiconductor layer has been get rid of, furthermore, contact resistance has been significantly lowered (the contact resistance of the BGTC devices can be significantly reduced from 200 kΩ cm to 1.8 kΩ cm in TGBC devices). During the preparation of bottom contact devices, the source/drain electrodes are pre-deposited on the substrate. In one hand, the damage on the organic semiconductor layer from source/drain evaporation process could be avoided. In another hand, devices with high accuracy could be fabricated by employing the conventional lithography techniques applied in inorganic micro-electronics, in this way, the device integration could be improved. (M. Mas-Torrent et al., Chemical Reviews, 2011, 111, 4833 (2011)). To enhance the device performance, selective modification at the contact between organic semiconductor layer and source/drain electrodes is usually required, for bottom contact devices, the highly selective patterned modification on the electrodes could be realized without destroying the organic semiconductor layer. Moreover, the modification methods are more variable than those for top contact devices, including solution dipping method, vapor deposition method and evaporation method. Besides, since the organic semiconductor layer located beneath the dielectric layer, the active layer is protected by dielectric layer, the stability of semiconductor devices could be improved as well as tolerance to water/oxygen, which is beneficial for application in actual production and daily use.

The performance of organic semiconductor is dependent of organic semiconductor materials, morphology of organic semiconductor layer, effective coverage ratio and the synergistic integration of three factors aforementioned with device structures. Changing any of these factors will have a significant impact on device performance (C. Reese et al., Materials Today, 10, 3(2007)). Organic semiconductor layer is a key role as active layer in realizing electrical/optoelectrical performance. According to the ordering of molecular packing in the structure of materials, from low to high, organic semiconductor layer usually exists as amorphous, polycrystalline or single-crystallin states. The highly-ordered organic semiconductor layer has been proved to be an efficient way to obtain high performance semiconductor devices, since the carrier mobility and excitons diffusion length are strongly dependent of ordering of molecular packing. Carrier mobility is also termed as mobility. For field-effect transistors, the performance mainly depends on mobility, threshold voltage and on/off ratio. In particular, mobility is a key parameter for device performance, mobility μ (cm² V⁻¹ s⁻¹) refers to the proportionality constant between the magnitude of an applied electric field and the velocity it imparts on a charge carrier.

For a same material, organic single crystal has highly ordered structure, no boundaries and less defects compared with its amorphous or polycrystalline counterparts. It leads to a superior charge carrier mobility in organic single crystals, which is favorable in thin-film semiconductor devices for charge transport. Furthermore, high mobility organic semiconductor devices could be easily obtained. For example, the devices based on amorphous or polycrystalline rubrene have mobilities around 10⁻³-10⁻⁴ cm² V⁻¹ s⁻¹. However, the highest mobility of single-crystalline rubrene semiconductor devices is about 40 cm² V⁻¹ s⁻¹. It's easy to find the mobility exhibited is nearly 5 orders of magnitude higher than those in amorphous or polycrystalline counterparts, and faster operation speed of organic devices is achieved. (J. Takeya et al., Applied Physics Letters 90, 102120 (2007)).

In order to maintain the morphology perfection of organic semiconductor layer, the morphology is supposed to remain basically unchanged during growth. Especially for organic single-crystalline semiconductor layer based on organic semiconductor single-crystal thin film, if the morphology has changed or deformed, the defects will be introduced. Eventually, the charge transport could be severely impeded by defects and the performance of organic semiconductor devices might be suppressed.

Similarly, the effective coverage ratio fc of organic semiconductor layer plays an essential part in achieving high performance organic semiconductor devices. The fc is defined as the ratio of the effective area to total area in the channel of organic semiconductor devices, notably, the effective area is continuous along the channel direction. For example, in single-crystalline organic semiconductor devices, the organic semiconductor layer is composed of single-crystal thin film from organic semiconductor. The single-crystal thin film of organic semiconductor is comprised of multiple crystals, which are existed as single-crystalline states. The effective coverage ratio could be divided into two dimensions, one is lengthwise direction (which is parallel to the growth direction of crystals) and the other is vertical direction (which is perpendicular to the growth direction of crystals). The lengthwise directional effective coverage ratio f_{cr} refers to the ratio of the continuous length of crystals in multiple channels to total length of channels. The f_{cr} reflected the contribution of organic single-crystalline semiconductor thin film to the substrate at the crystal growth direction. The vertical directional effective coverage ratio f_{cp} refers to the ratio of the sum of crystal widths in the designated channel to the channel width. The f_{cp} reflected the contribution of the sum of crystal widths to the substrate at a direction which is perpendicular to the crystal growth. As FIG. 5 illustrated, for the lengthwise directional effective coverage ratio, f_{cr}=(c_{L1}+c_{L2}+ . . . +c_{Lm})/(L₁+L₂+ . . . +Lₘ), m is a positive integer greater than or equal to 5, c_{L1}, c_{L2}, . . . , c_{Lm} represent continuous lengths of crystals c_{L} in the 1, 2, . . . , m channels in m adjacent and continuous channels, respectively. And L1, L2, . . . , Lm represent the lengths L of the 1, 2, . . . , m channels covered by crystals, respectively. For The vertical directional effective coverage ratio, f_{cp}=(k₁+k₂+ . . . +kₙ)/W, k₁, k₂, . . . , kₙ represent the contact widths k between the 1, 2, . . . , n crystals and source/drain electrodes, respectively; W represents width of channel, n is a positive integer greater than or equal to 8. Higher f_{cr} is obtained with better the continuity of crystals. In a channel with same length, larger contact length (k) between crystal and source/drain electrodes results in smaller gap width (g). The width of actual transport pathway for charge carriers gets larger with higher f_{cp}, and better performance of semiconductor devices could be realized. When gap width (g)=0, the f_{cp} could achieve 100%. Ideally, for organic single-crystalline semiconductor thin films, it is necessary to achieve a sufficiently high effective coverage in both the lengthwise direction and the vertical direction. That is, the organic single-crystalline semiconductor thin films are required to be able to achieve complete/full coverage on a substrate of arbitrary shape or arbitrary size. The complete/full coverage could be defined as f_{cr}≥80% and f_{cp}≥50% in organic single-crystalline semiconductor thin films. However, the complete/full coverage cannot be realized with current technology.

In summary, the ideal industrialized organic semiconductor devices have 4 requirements as follows: 1) the device configuration is bottom contact structure; 2) the organic semiconductor layer is single-crystalline; 3) the morphology of organic semiconductor layer is single-crystal thin film of organic semiconductor with uniform growth; 4) the aforementioned organic single-crystalline semiconductor thin film has effective coverage as large as possible, and it is best to achieve complete/full coverage on a substrate of arbitrary shape or arbitrary size. Better electrical/optoelectrical performance could be obtained if the 4 requirements above-mentioned are fulfilled. Furthermore, the high integration of multiple device arrays on a same organic single-crystalline semiconductor thin film should be realized. However, since the molecules in organic semiconductor single crystals are required to be arranged regularly and periodically in three-dimensional space, thus, the growth of organic semiconductor single crystals are more difficult compared with their polycrystalline or amorphous counterparts. Extraordinary control is needed for regulation on the morphology of single crystals, and it is extremely difficult to achieve. (M. Niazi et al., Advanced Functional Materials, 26, 2371 (2016)). Using current technology cannot realize complete/full coverage of organic single-crystalline semiconductor thin film in bottom contact structure in laboratory or factory.

In the past, large-size/large-area/large-scale organic single-crystalline semiconductor thin films with controllable morphology have been reported. For example, organic semiconductor single crystals could be prepared up to several hundreds of micrometers in length by utilizing drop-casting, spin-coating, printing, meniscus-guided coating and so on. (S. S. Lee et al., Advanced Materials, 21, 3605 (2009); H. Li et al., Advanced Materials, 24, 2588 (2012); H. Minemawari et al., Nature, 475, 364(2011)). It is wildly known that the surface roughness of growth interface will affect the molecular packing, resulting in morphology change of organic semiconductor crystals as well as non-uniformly growth. (W. Shao et al., Chemical Science, 2, 590(2011)). The growth interface refers to the contact interface where organic semiconductor molecules grow. According to the different device configuration, the growth interface of bottom contact devices is the contact interface between organic semiconductor layer and substrate, for top contact devices the growth interface is the contact interface between organic semiconductor layer and dielectric layer. Growth interface with large roughness is easy to induce nucleation when crystallizing, and orientation and alignment of crystals are thus random. (H. Li et al., MRS Bulletin, 1, 38(2013)). The root mean square roughness (RMS), a parameter for roughness characterization, refers to the root mean square value of the contour deviation from the average line within the sampling length. Therefore, smooth or flat growth interface with very low roughness is the prerequisite for uniform growth of organic crystals. Moreover, smooth or flat growth interface are needed to achieve uniform growth of organic single-crystalline semiconductor thin film with high effective coverage ratio or even complete/full coverage.

However, in organic single-crystalline semiconductor devices based on bottom contact structure, thus organic single-crystalline semiconductor layer is deposited on a bottom contact substrate. Organic semiconductor layer as active layer is key to device function, the organic semiconductor layer aforementioned is composed of organic single-crystalline semiconductor thin film, and the organic single-crystalline semiconductor thin film is consisting of multiple crystals, the crystals aforementioned are from semiconductor and exist as single-crystalline states. Source/drain electrodes, with key functions as injecting and extracting charge carriers, are located on the growth interface, which is perpendicular to the direction of crystal growth. To obtain working electrodes, source/drain electrodes usually have certain thickness over 10 nanometers and even some of them could be up to tens of nanometers, where the roughness of growth interface is greatly increased. It could be assumed that semiconductor devices based on bottom contact structure has rough growth interface, and the RMS of rough growth interface is several or even dozens of times that of smooth growth interface. The source/drain electrodes construct barriers like high hills, thereby the nucleation and front growth of crystals are influenced, resulting in less ordering of molecular packing. It makes the crystals unable to achieve uniform growth when crossing the electrodes. That is, the morphology change of the crystal appears before crossing the electrode 100, at the electrode edges 101 or 103, on the electrode 102, or after crossing the electrode 104, therefore, hindering the efficient charge transport of carriers as well as increasing the anisotropy of charge transport. Ultimately, the electrical performance of semiconductor devices is greatly reduced. The morphology change of crystals refers to the change that is easy to be observed. Specifically, it can refer to the change that can be observed under an optical microscope or a polarized optical microscope with appropriate magnification. FIG. 9 is a schematic diagram of various morphology changes of crystals. For instance, packing defects and deformation of crystals occur near the edges of electrodes, the deformation above-mentioned including cracks, pits and distortion of crystals and so on (FIG. 9F). Width change (FIG. 9C—FIG. 9D), shape change (FIG. 9G) and curving (FIG. 9H) of crystals are also included. Besides, the alignment of crystal arrays are easily affected by electrodes, leading to branching, intersection, and alignment disturbance (FIG. 9E). In the FIG. 10 of polarized optical micrograph, the actual morphology changes of crystals could be observed. Both growth direction and width of crystals on electrodes changed in FIG. 10A-FIG. 10B. Deformation and defects of crystals were shown at the edges of electrodes in FIG. 10C and FIG. 10F. In FIG. 10D-FIG. 10E, the curving and branching of crystals appeared.

In view of the above-mentioned problems, the improvements of current technology are included as follows: patterning the substrates for modifying alignment of crystals externally. However, this method relies on patterned templates, which requires sophisticated micro channels with extra preparation process. Here, the crystal growth is modified and constrained by the micro channels in the meantime. The effective coverage ratio reported in this article only has one dimension in vertical direction, and the f_{cp} is about 15-30%, which means it cannot achieve sufficiently high effective coverage ratio at both lengthwise and vertical direction of crystal growth, far from meeting the requirements of high-performance devices (W. Deng et al., Materials Today, 24, 17(2019)). Since the control on morphology of organic semiconductor single crystals is difficult, to circumvent this problem, adjusting the material composition are adopted to achieve large-scale growth. For example, blending organic semiconductor small molecules with insulting polymers to replace organic semiconductor single crystals is used to avoid the problem, as it mentioned in (M. Niazi et al., Nature Communications, 6, 8598 (2015)), “The stringent performance requirements for organic thin-film transistors (OTFTs) in terms of carrier mobility, switching speed, turn-on voltage and uniformity over large areas require performance currently achieved by organic single-crystal devices, but these suffer from scale-up challenges. Here we present a new method based on blade coating of a blend of conjugated small molecules and amorphous insulating polymers to produce OTFTs”. Although this method has improved the morphology of thin-film devices on bottom contact structure in some degree, the performance of material is sacrificed. Because of the bending with insulting polymers, organic semiconductor thin film are no longer single-crystalline. The thin film obtained has phase separation, and the phase separation is limited by the modification layer on electrodes in different area. When insulating polymers are sandwiched between the organic semiconductor layers inside of the blends, the compactness of crystalline films is affected. If insulating polymers are located at the outer surface of blends, the contact resistance between semiconductor layer and electrodes, resulting in deteriorating the electrical performance of devices. Transferring previously prepared crystals from vapor phase method or liquid phase method via flexible substrate are of certain could be applied on substrates with pre-deposited electrodes to fabricate bottom contact devices. For instance, physical transfer method or chemical etching method are included. Nevertheless, there are still some problems existed in transfer method: 1) the transferring is challenging, damage on crystals might appear during the transfer process; 2) contact issues of devices are exhibited, and intimate contact might be impeded when laminating crystals from original flexible substrates to target substrates with pre-deposited electrodes; 3) the procedures are not facile, and it is difficult to laminate crystals precisely at designated locations, leading to reduction of device integration, as well as hampering the large-scale production. Therefore, in a perspective of industrialization, utilizing in-situ grown organic single-crystalline semiconductor layer is an ideal way to fabricate bottom contact devices.

In a conclusion, the ideal organic semiconductor devices for industry application are organic single-crystalline semiconductor devices based on bottom contact structure. The organic single-crystalline semiconductor thin film aforementioned has a morphology of uniform growth, and it is able to achieve sufficient high effective coverage ratio even complete/full coverage of morphology on a substrate of arbitrary shape or arbitrary size. The morphology of uniform growth refers to the crystal morphology remaining basically unchanged before crossing the electrode 100, at the electrode edges 101 and 103, on the electrode 102, and after crossing the electrode 104. Channels with highest quality for efficient charge transport of carriers are provided, thus optimal device performance could be guaranteed. However, current technology cannot prepare organic single-crystalline semiconductor devices based on bottom contact structure with morphology of uniform growth. There are several challenges: 1) only on smooth or flat growth interface with extremely low roughness, organic single-crystalline semiconductor thin films with morphology of uniform growth could be obtained. However, pre-deposited electrodes on bottom contact substrates have greatly increased the roughness of growth interface. Consequently, organic single-crystalline semiconductor thin films with morphology of uniform growth are unavailable; 2) organic single-crystalline semiconductor thin films have relatively low effective coverage ratio in organic single-crystalline semiconductor devices. It is hard to improve the effective coverage ratio. Furthermore, it is impossible to achieve a sufficiently high effective coverage ratio in both the lengthwise direction and the vertical direction at the same time, which is far from meeting the requirement of excellent device performance; 3) in order to achieve effective coverage ratio as large as possible, preparation of organic single-crystalline semiconductor thin film with complete/full coverage on a substrate of arbitrary shape or arbitrary size is demanded. Theoretically, a smooth or flat growth interface is required. Because of the non-smooth growth interface of devices based bottom contact structure, it cannot obtain an organic single-crystalline semiconductor thin film with complete/full coverage on bottom contact structure; 4) since organic semiconductor single crystals require periodical molecular packing inside, the extraordinary control over morphology is needed. The growth condition is very strict, thus combining single crystallinity of materials with morphology of uniform growth and high effective coverage ratio is incapable. However, ideal devices need to satisfy the requirements above-mentioned at the same time. That is, acquiring organic single-crystalline semiconductor thin films on bottom contact growth interface with morphology of uniform growth and high effective coverage ratio. Unfortunately, it cannot be realized by current technology; 5) the control over growing organic semiconductor single crystals is very complicated for sophisticated modification on morphology, and it is difficult to achieve large-scale industry production; 6) for industrialization, it is incapable of realizing unlimited in-situ growth of organic single-crystalline semiconductor thin film on a bottom contact substrate of arbitrary shape or arbitrary size. Current technologies have not solved any of the problems aforementioned, not to say that solving 6 problems above-mentioned at a same time. Therefore, huge challenges are raised, such as getting uniformly grown organic single-crystalline semiconductor thin films in bottom contact structure, realizing complete/full coverage of morphology on a substrate of arbitrary shape or arbitrary size. The challenges aforementioned may act as roadblocks for large-scale industry application of organic single-crystalline semiconductor devices.

### SUMMARY

In view of the shortcomings of the current technology, the technical problem to be solved by the present invention is to provide an organic single-crystalline semiconductor structure and a preparation method thereof. Based on the problems existing in the prior art, the inventors overcome obstacles in the prior art and limitations in thinking. Unexpectedly, organic single-crystalline semiconductor thin films with morphology of uniform growth and high effective coverage ratio are successfully prepared on the growth interface in bottom contact structure, even complete/full coverage could be achieved. Besides, unlimited in-situ growth of organic single-crystalline semiconductor thin film are able to realize on a bottom contact substrate of arbitrary shape or arbitrary size. The 6 problems of organic single-crystalline semiconductor devices based on bottom contact structure that are insoluble in the prior art could be resolved simultaneously in the present invention. For organic semiconductor devices, the organic single-crystalline semiconductor thin films aforementioned have satisfied the most ideal situation of both morphology and material, which is essential for realizing ideal organic semiconductor devices for industrial application. The organic singe-crystalline semiconductor thin film provides high-quality channels with maximize area for efficient charge transport of carriers. In the field of industry, organic semiconductor devices based on organic single-crystalline semiconductor structure aforementioned have multiple advantages: such as best performance of charge transport, highest device integration, best stability, facile preparation, combination with flexibility, possibility of realizing in-situ complete/full coverage and so on. This offer a foundation for large-scale industrial preparation of in-situ organic semiconductor devices within almost ideal situations above-mentioned, which is breaking through the bottleneck of current technology.

The present disclosure adopts the following technical solutions:

The first technical problem to be solved by the present disclosure is to provide an organic single-crystalline semiconductor structure. The structure comprises substrate, growth-assistant layer, electrodes and organic single-crystalline semiconductor layer. The last three are deposited sequentially from bottom to top on the substrate. The organic single-crystalline semiconductor layer aforementioned is grown on the growth-assistant layer and electrodes and is also in contact with them. The organic single-crystalline semiconductor layer is consisting of organic single-crystalline semiconductor thin film, and the thin film is constructed by organic semiconductor single crystal arrays. The morphology of organic semiconductor single crystal array keeps basically unchanged before crossing the electrode 100, at the electrode edges 101 and 103, on the electrode 102, and after crossing the electrode 104. That is, the organic single-crystalline semiconductor thin film of present invention has a morphology of uniform growth.

The organic semiconductor single crystal array is composed by crystals. The material of crystals is semiconductor, and the crystals exist as single-crystalline states. The basically unchanged morphology of organic semiconductor single crystal array refers to basically unchanged crystal morphology as well as consistent alignment before and after crossing the electrodes. The basically unchanged crystal morphology could refer to each crystal in the organic semiconductor single crystal array remaining basically unchanged in growth direction, crystal width, crystal shape and consistence of growth. The basically unchanged morphology of organic semiconductor single crystal array refers to its morphology of uniform growth.

The morphology of organic single-crystalline semiconductor thin film containing: the morphology of organic semiconductor single crystal array, the morphology of crystal and the alignment of organic semiconductor single crystal array. The morphology aforementioned could be characterized by optical microscopy, scanning electron microscopy, atomic force microscopy and so on. Currently, optical microscopy is the most commonly used method with the largest scale of characterization and also the easiest way to promote. For example, the specific characterization method of optical microscopy is described as follows: the organic semiconductor structure aforementioned is placed under the optical microscope with appropriate magnification (it could be tens or hundreds of times, for instance, FIG. 8 is with the magnification of 100 times). Next is capturing the optical microscope image and polarized optical microscope image (i.e. optical microscope image between crossed-polarizers) of organic single-crystalline semiconductor thin film. The images of organic single-crystalline semiconductor thin film above-mentioned should contain areas before crossing the electrode, at the electrode edges, on the electrode, and after crossing the electrode at the same time. Then, the morphology of organic single-crystalline semiconductor thin film in both images should be analyzed. When uniform color or the change of color appears, it could be inferred that crystals obtained is not single-crystalline (as illustrated in FIG. 10B-FIG. 10F, the emergence of different color patch and color change account for polycrystalline organic semiconductor thin film). The crystals with the basically uniform color are single crystals (as illustrated in FIG. 11, crystals have basically uniform color in itself and between each other as well). By observing the obtained optical microscope images or polarized optical microscope images, it can be determined whether the morphology of the organic semiconductor single crystal array is basically unchanged, that is, whether the organic semiconductor single crystal array has a uniform growth morphology.

The opposite concept of “the morphology of the organic semiconductor single crystal array is basically unchanged” is “the morphology of the organic semiconductor single crystal array is changed”, which could refer to the change in the crystal morphology and/or the inconsistent alignment of the organic semiconductor single crystal array before and after crossing the electrodes. Whether the change of crystal morphology or the inconsistent alignment of the organic semiconductor single crystal array before and after crossing the electrode, it could be regarded as “the morphology change of the organic semiconductor single crystal array”.

The opposite concept of “basically unchanged crystal morphology” is “changed crystal morphology”. The change of crystal morphology could be referred to the change of any parameters of crystal growth for each crystal that constitutes the organic semiconductor single crystal array, including the growth direction of crystal, crystal width, and crystal shape. For example, the change of morphology could be visualized in optical microscope images or polarized optical microscope images: the packing defects of crystals near the edges of electrodes, deformation of crystals near the edges of electrodes such as cracks, pits, distortion and so on (FIG. 9F), the change of crystal width (FIG. 9C-FIG. 9D), the change of crystal shape (for example, spherulites at the electrodes in FIG. 9G) and curving of crystals (FIG. 9H). The change of crystal width aforementioned refers to the absolute value of the ratio (|R|) of the difference between the width of the crystal at the edge of the electrode 101 and 103 and the edge of the electrode 103 over 20%, that is, |R|>20%. |R|=(|(k₁₍₁₀₁₎−k₁₍₁₀₃₎)/k₁₍₁₀₃₎|+|(k₂₍₁₀₁₎−k₂₍₁₀₃₎)/k₂₍₁₀₃₎|+ . . . +|(kₙ₍₁₀₁₎−kₙ₍₁₀₃₎)/kₙ₍₁₀₃₎|)/n*100%, k₁₍₁₀₁₎, k₂₍₁₀₁₎, . . . , kₙ₍₁₀₁₎ are the widths of the 1, 2, . . . , n crystals in contact with the electrode edge 101, respectively, k₁₍₁₀₃₎, k₂₍₁₀₃₎, . . . , kₙ₍₁₀₃₎ are the widths of the 1, 2, . . . , n crystals in contact with the electrode edge 103, where n is a positive integer greater than or equal to 8, as shown in FIG. 9D. FIG. 10 are polarized optical microscope images, some practical phenomena of the change of crystal morphology could be observed. In FIG. 10A-FIG. 10B, the growth direction and width of crystals on the electrodes had observable changes. In FIG. 10C and FIG. 10F, defects and deformation of crystals occurred at the edges of electrodes. In FIG. 10D-FIG. 10E, the curving of crystal was visualized.

The opposite concept of “the alignment of the organic semiconductor single crystal array is consistent before and after crossing the electrode” is that “the alignment of the organic semiconductor single crystal array is inconsistent before and after crossing the electrode”. That is, organic semiconductor single crystal array has inconsistent orientation before crossing the electrode 100, at the electrode edges 101 and 103, on the electrode 102, and after crossing the electrode 104. For example, in the optical microscope images or polarized optical microscope images, the orientation of crystal array was easily affected by electrodes, leading to branching, intersection, and alignment disturbance FIG. 9E. In FIG. 10D-FIG. 10E, the branching crystals were shown.

Compared with those thin films with morphology change, the present invention provides a high-quality organic single-crystalline semiconductor thin film with a morphology of uniform growth, and improves the performance of charge carrier injection, transport and extraction. Also, the charge carriers can be efficiently injected and extracted at the contact with electrodes (i.e. at the edges of electrodes and on the electrodes), which is beneficial for realizing the intrinsic performance of organic semiconductor single crystals. And the challenges that charge traps/structural defects are easily occurred at the contact with electrodes in the organic single-crystalline semiconductor devices with bottom contact structure in the prior art are overcome.

In some embodiments, the organic semiconductor single crystal array aforementioned is obtained by uniform growth crossing the electrodes, and the organic semiconductor single crystal array is constituted by aligned crystals, as shown in FIG. 8, FIG. 9A-9B, and FIG. 11. The uniform growth crossing the electrodes refers to crystals that constitute the organic semiconductor single crystal array are uniformly growing before crossing the electrode 100, at the electrode edges 101 and 103, on the electrode 102, and after crossing the electrode 104. Thus, the morphology of organic semiconductor single crystal array keeps basically unchanged before crossing the electrode 100, at the electrode edges 101 and 103, on the electrode 102, and after crossing the electrode 104. The term “before the electrode 100 and after the electrode 104” refers to the growth area of the crystals before and after encountering the electrodes along the crystal growth direction, respectively; the term “electrode edges 101 and 103” refers to the edges where the electrodes are in contact with growth-assistant layer. As displayed in FIG. 5, FIG. 8, and FIG. 9A-9B, the perfect morphology is ribbon-like crystal array with approximately linear arrangement.

The growth-assistant layer is necessary for realizing uniform growth of organic single-crystalline semiconductor thin film crossing the electrodes. During the nucleation and crystallization process of organic semiconductor molecules, the growth-assistant layer plays an essential part in modification for packing ordering, as well as the distribution, degree and interaction of organic semiconductor molecular aggregates. It contributes for improving the situation that crystal growing is hindered by the height difference between the electrodes and the plain substrate without pre-deposited electrodes. There is a huge difference in surface chemistry between the electrodes and the plain substrate without pre-deposited electrodes, thus, morphology is usually changed at the contact with electrodes such as increased grain boundaries, reduced grain size and so on. In some cases, completely different molecular stacking modes might be caused on the electrodes or near the electrodes compared with those on the plain substrate without pre-deposited electrodes. However, the growth-assistant layer reduces this difference, it assists the growth of organic semiconductor crystals crossing the electrodes with basically unchanged morphology. On the other hand, the growth-assistant layer is also helpful for improving wetting of solutions containing organic semiconductors, which is optimal for achieving complete/full coverage of organic single-crystalline semiconductor thin film.

In some embodiments, the organic single-crystalline semiconductor thin film can realize complete/full coverage on a substrate of arbitrary shape or arbitrary size. That is, the growth of organic single-crystalline semiconductor thin film on the substrate is not restricted by the shape or size of the substrate. The complete/full coverage refers to the organic single-crystalline semiconductor thin film having sufficiently high effective coverage ratio at both lengthwise direction and vertical direction of crystals.

In some embodiments, the complete/full coverage could refer to effective coverage ratio at lengthwise direction of crystal (lengthwise directional effective coverage ratio) f_{cr}≥80%, and the effective coverage ratio at vertical direction of crystal (vertical directional effective coverage ratio) f_{cp}≥50%.

Preferably, f_{cr}≥90%, f_{cp}≥5 0%.

More preferably, f_{cr}≥80%, f_{cp}≥80%.

As the most preferably, f_{cr}≥90%, f_{cp}≥80%.

In some embodiments, for the lengthwise directional effective coverage ratio f_{cr}+(c_{L1}+c_{L2}+ . . . +c_{Lm})/(L₁+L₂+ . . . +Lₘ), m is a positive integer greater than or equal to 5, c_{L1}, c_{L2}, . . . , c_{Lm} represent continuous lengths of crystals c_{L} in the 1, 2, . . . , m channels in m adjacent and continuous channels, respectively. And L₁, L2, . . . , Lₘ represent the lengths L of the 1, 2, . . . , m channels covered by crystals, respectively. For the vertical directional effective coverage ratio, f_{cp}=(k₁+k₂+ . . . +kₙ)/W, k₁, k₂, . . . , kₙ represent the contact widths k between the 1, 2, . . . , n crystals and source/drain electrodes, respectively, W represents width of channel, n is a positive integer greater than or equal to 8.

In order to achieve the possible maximum effective coverage ratio of organic single-crystalline semiconductor thin film at both the lengthwise direction and the vertical direction simultaneously in the continuous channels (i. e. sufficiently high effective coverage ratio at both the lengthwise direction and the vertical direction simultaneously), complete/full coverage of organic single-crystalline semiconductor thin film needs to be realized on a substrate of arbitrary shape or arbitrary size. There are two indicators to evaluate whether the complete/full coverage is achieved: the effective coverage ratio in the lengthwise direction and the effective coverage ratio in the vertical direction. When f_{cr}≥80% and f_{cp}≥50%, efficient charge transport pathways are able to be provided for carriers as well as better electrical performance. Therefore, if the two indicators are met, it could be considered as achieving the complete/full coverage. At present, in this field, the technology for preparing large-area organic single-crystalline semiconductor thin films is limited in the laboratory, and the complete/full coverage on a substrates of arbitrary shape or arbitrary size cannot be achieved.

The effective coverage ratio of single-crystalline organic semiconductor thin film reported in the prior art only has one indicator, which represents the effective coverage ratio in the vertical direction. It declares that organic single-crystalline semiconductor thin film in the prior art can only achieve effective covering in the vertical direction, but not in the lengthwise direction. Further, the effective coverage ratio in the vertical direction reported is generally low, indicating that the complete/full coverage described in the present invention cannot be obtained in the prior art. For example, as illustrated in FIG. 22, FIG. 22A and FIG. 22A-22B are FIGS. 2(d) and 4(a) in W. Deng et al., Materials Today, 24, 17 (2019), respectively. The arrow's direction in the figure represents the lengthwise direction, and the vertical direction is the direction perpendicular to the arrow' direction. The article mentioned that the coverage ratio of DPA crystals in one direction is only 15-30% (“the surface coverage of DPA crystals on the substrate is estimated to be about 15-30%”, FIGS. 2(d) and 4(a)). Through the arrow's direction in FIG. 22A-22B, it can be deduced that the surface coverage described in the text represents the effective coverage ratio in the vertical direction. In addition, those skilled in the art can understand that the range of the selected area where the morphology of organic single-crystal thin film is characterized could be deduced by the scale bar in the morphology characterization images. The scale bar in FIG. 22A is 20 μm, it shows that a tiny area is selected in the entire substrate (a 4-inch silicon wafer, with a diameter about 100 mm) to characterize the morphology of the organic single-crystal thin film. It further shows that it is impossible to obtain effective coverage ratio in both directions completely. In summary, sufficiently high effective coverage ratio in the two dimensions including the lengthwise direction and the vertical direction cannot be achieved simultaneously in the prior art. And it is far from meeting the requirements of high-performance devices, which is a huge technical challenge. However, the organic single-crystalline semiconductor thin films with a complete/full coverage are able to overcome this problem, based on which more complex organic semiconductor heterostructures can be fabricated additionally, and more diversified functions in electronics/optoelectronics could be developed. Moreover, organic single-crystalline semiconductor thin films with high effective coverage ratio can be used for preparing highly integrated electronic device arrays, which provides a possibility for developing new-generation integrated devices. The large-size/large-area/large-scale organic single-crystalline semiconductor thin film mentioned in the prior art were able to be prepared only on a smooth or flat substrate with a regular size in micrometers or several centimeters. And the complete/full coverage of organic single-crystalline semiconductor thin film cannot be achieved on rough substrates in bottom contact structure, not to mention on a substrate of arbitrary shape or arbitrary size. While the large-area organic single-crystalline semiconductor thin film provided by the present invention can realize unlimited continuous growth on a bottom contact substrate, and a complete/full coverage of organic semiconductor single crystal array up to tens of centimeters can be obtained.

In some embodiments, the electrodes contact with the growth-assistant layer with protruding outside of the growth-assistant layer. The electrodes are in contact with the growth-assistant layer in an upper type and/or embedded type, the upper type refers to the upper surface of growth-assistant layer in contact with the lower surface of the electrodes, and the embedded type refers to the electrodes half-embedding or penetrating the growth-assistant layer. The growth-assistant layer is located underneath the electrodes, as shown in FIG. 4, the electrodes are in contact with growth-assistant layer in an upper type and/or embedded type, the upper type (FIG. 4A) means that the upper surface of the growth-assistant layer is in contact with the lower surface of the electrode, and the embedded type (FIG. 4B) means that the electrodes are half-embedding or penetrating the growth-assistant layer. The half-embedding specifically refers to the growth-assistant layer in contact with both the lower surface and the side surface of the electrodes. The penetrating specifically refers to the growth-assistant layer contacting only with the side surface of the electrodes. The electrodes are arranged on growth-assistant layer in either or both of the upper type and the embedded type (FIG. 4C). Therein the electrodes can be arranged in contacting with growth-assistant layer only in the upper type, or only in the embedded type, and it can also be in both the upper type and the embedded type at the same time. The arrangement of electrodes aforementioned could be ordered or random.

The location relationship that the growth-assistant layer beneath the electrodes could be achieved by depositing the growth-assistant layer before the electrodes. By partially etching the growth-assistant layer using ultraviolet ozone/laser/plasma or other methods after depositing it and then depositing the electrodes in etched pits, the location relationship that the growth-assistant layer with embedded electrodes can be achieved. When the growth-assistant layer is located above the electrodes, it will separate the organic semiconductor layer from the electrodes, so that carriers cannot be directly injected into the organic semiconductor layer from the electrodes because of the hinderance from the growth-assistant layer, resulting in device failure. Therefore, the location relationship that the growth-assistant layer beneath the electrodes or with the electrodes embedded can ensure the uniform growth of organic single-crystalline semiconductor thin film across the electrodes while maintaining the integrity function of the organic semiconductor device.

In some embodiments, as FIG. 5 displayed, the organic single-crystalline semiconductor thin film is a well-aligned organic semiconductor single crystal array, which is composed of multiple separate and independent linear-type elements (the black solid stripes in the left side of FIG. 5). The multiple linear elements are arranged in a linear-type arrangement, and the linear-type arrangement may refer to the well-aligned orientation/arrangement of the linear elements along the crystal growth direction. The “well-aligned orientation/arrangement” could mean that the linear elements are almost parallel. The linear elements grow uniformly before crossing the electrode 100, at the electrode edges 101 and 103, on the electrode 102 and after crossing the electrode 104, that is, the morphology of the linear element is basically unchanged before crossing the electrode 100, at the electrode edges (101 and 103, on the electrode 102 and after crossing the electrode 104, the linear element is an independent crystal with single-crystalline morphology.

In some embodiments, the well-aligned orientation/arrangement may refer to the degree of orientation F≥0.625; preferably, F≥0.95; more preferably, F=1 (the linear elements are parallel to each other).

In some embodiments, the detection method of F is: randomly selecting n linear elements of the organic single-crystalline semiconductor thin film as samples, where n is a positive integer greater than or equal to 10. And the crystal growth direction is taken as the reference direction. Take the angle between the direction of the longest dimension c of each linear element and the reference direction as the orientation angle A, the average value of the orientation angles of the n linear elements as Ā. And the degree of orientation F=0.5*(3*cos² Ā−1).

In some embodiments, the morphology of the linear element is pseudo one-dimensional (pseudo 1D, p1D) or pseudo two-dimensional (pseudo 2D, p2D); when the length c of a single crystal along the crystal growth direction is much larger than the width a of the crystal and the thickness b of the crystal, that is, when c/a≥500 and c/b≥500, the morphology is pseudo 1D; preferably, c/a≥1000, c/b≥1000; more preferably, c/b≥2000, a/b≥2000; when both the length c of a single crystal along the crystal growth direction and the width a of the crystal are much larger than the thickness b of the crystal, that is, when c/b≥500 and a/b≥500, the morphology is pseudo 2D; preferably, the linear element has a pseudo one-dimensional morphology; as the most preferable, the pseudo 1D linear element is a regular strip or ribbon.

In some embodiments, in the stereogram of linear element (FIG. 5), the top view of linear element is linear or facial form, and the thickness b of linear element is 2 nm to 400 nm; preferably, b is 5 nm to 200 nm.

In some embodiments, the thickness of linear element is highly uniform.

In some embodiments, the detection method of “the thickness of linear element is highly uniform” is: randomly taking p samples of linear elements in the organic single-crystalline semiconductor thin film and characterizing the thickness b of the linear elements, the average thickness of p linear elements is b̅, and p is a positive integer greater than or equal to 8, when b̅<10 nm, the coefficient of variation of the thickness of the linear element in p samples is ≤40%, when 10 nm≤b̅≤50 nm, the coefficient of variation of the thickness of the linear element in p samples is ≤30%, when b̅≥50 nm, the coefficient of variation of the thickness of the linear element in p samples is ≤20%, indicating that linear elements have highly uniform thickness; preferably, when b̅≤10 nm, the coefficient of variation of the thickness of the linear element in p samples is ≤30%, when 10 nm≤b̅≤50 nm, the coefficient of variation of the thickness of the linear element in p samples is ≤20%, when b̅≥50 nm, the coefficient of variation of the thickness of the linear element in p samples is ≤10%. The coefficient of variance is also called the “standard deviation rate”, which is the ratio of the standard deviation to the mean multiplied by 100%. The coefficient of variation is an absolute value that reflects the degree of dispersion of the data. The smaller the value of the coefficient of variation, the smaller the degree of dispersion of the data, indicating that the thickness of crystals is more uniform.

In some embodiments, the gap width g of each of the linear elements along the crystal growth direction is 0 mm to 1 mm; preferably, the gap width g≤10 μm.

The linearly arranged organic single-crystalline semiconductor thin film has well-aligned orientation/arrangement, providing a high-quality efficient transport pathway for charge carriers, as shown in FIG. 8 and FIG. 9A-9B, where FIG. 8 is the optical microscope image of organic single-crystalline semiconductor thin film that actually obtained. FIG. 9A-9B is the corresponding schematic diagram of FIG. 8, each black solid stripe in FIG. 9A-9B is a crystal, and each crystal is a linear element. FIG. 9B is a partial enlarged view within the dashed frame in FIG. 9A. The organic single-crystalline semiconductor thin film with regularity, uniform thickness, and well-aligned orientation/arrangement ensures the uniformity of the device, which is beneficial to control the resistance of the semiconductor devices and further improve the electrical performance of the devices. Organic single-crystalline semiconductor thin films with a perfect morphology on an industrial scale can only be obtained by coupling the ability to achieve complete/full coverage on substrates of arbitrary shape or arbitrary size with the above three properties simultaneously. These organic single-crystalline semiconductor thin films greatly increase the utilization area of devices, and make the evaporation of electrodes and the preparation of highly integrated devices more convenient, eventually the technical difficulties that organic single-crystalline semiconductor devices are difficult to integrate for industry are overcome.

Single crystals grown by small molecules of easy-crystallized organic semiconductors are now commercially available. If the thickness of the single crystal array is less than 2 nm, some defects may exist on the surface or inside of the single crystal obtained, thus the performance of charge carriers transport without doping might be reduced due to the defects as charge traps. If the thickness of the single crystal array exceeds 400 nm, the material consumption increases, and the access resistance of the device also increases, which causes an increase in the device's demand for operating voltage, the threshold voltage becomes larger as well, ultimately the device performance would be affected. In addition, due to the flexibility of the dielectric layer, the roughness and undulation of the upper surface of the dielectric layer coated on single crystals will be affected by the thickness of the organic single-crystalline semiconductor thin film, which may cause poor contact between gate electrodes and the dielectric layer. Therefore, appropriate thickness of the linear element can ensure the preparation of high-performance devices while saving the cost of raw materials.

In some embodiments, the growth-assistant layer is an organic insulating thin film. Preferably, the water contact angle CA_{water} that between the organic insulating thin film aforementioned and water is 30° to 120°; more preferably, the CA_{water} is 60° to 100°.

In some embodiments, the material of the organic insulating film has a π-conjugated system, and the π-conjugated system refers to a system wherein conjugated π bonds are able to form. And the it-conjugation could be extended by conjugated units.

In some embodiments, the dielectric constant of the organic insulating film is ≤20; preferably, the dielectric constant is ≤12.

In some embodiments, the material of organic insulating film is selected from any one or more of self-assembled small molecules containing silyl groups, self-assembled small molecules containing phosphate groups, self-assembled small molecules containing thiol groups, dielectric polymers.

In some embodiments, the material of the organic insulating film is a dielectric polymer or a mixture thereof, and the selected polymer is crosslinked or non-crosslinked; preferably, the polymer contains any one or more blocks from polystyrene, polymethyl methacrylate, polyvinyl alcohol, polyvinyl chloride, polyvinylpyrrolidone, polysiloxane, polyimide, polyethylene, polyethylene oxide, polyvinylphenol, polyethylene naphthalate, polyethylene terephthalate, polyethersulfone, benzocyclobutene, perfluoroalkyl vinyl ether, polyfluoroethylene.

Coating growth-assistant layer on the substrate can be used to assist crystals to achieve uniform growth crossing the electrodes, and organic single-crystalline semiconductor thin films with well-aligned orientation/arrangement could be obtained. Since the growth-assistant layer is located beneath the organic single-crystalline semiconductor thin film and the electrodes, its properties will affect the injection and extraction of the electrodes in devices. Thus, organic insulating materials should be adopted for the growth-assistant layer, otherwise it may result in a normally open state in the device, that is, there will be still a current flowing even at 0V, which consumes a lot of energy and the switching effect cannot be realized. The surface of growth-assistant layer has a certain degree of hydrophobicity. Choosing a material with a suitable water contact angle can ensure that the interface is partially hydrophobic but not too hydrophobic to reduce the affinity with organic solvents, which is conducive to increasing the affinity between growth interface and organic solution. This enables crystals to grow continuously on the surface of the substrate with pre-deposited electrodes and to across the certain-height electrodes without changing the morphology. And the crystal quality of the well-aligned organic single-crystalline semiconductor thin film grown will be improved, thereby the stability of the device based on this structure is enhanced. The specific material of growth-assistant layer can be determined according to the selected molecules of semiconductor layer and the type of organic solvent. Preferably, the growth-assistant layer has a π-conjugated structure, thus, it would lead to interactions with organic semiconductor molecules which also have a π-conjugated system. A guiding effect on the arrangement and stacking of molecules could be obtained. The dielectric constant reflects the polarity and density of atoms and bonds in the growth-assistant layer. And a smaller dielectric constant usually means a low polarity of the growth-assistant layer. It is helpful to increase the affinity of commonly used organic solvents with low polarity, a good growth environment for obtaining a complete/full coverage morphology of organic semiconductor single crystals is provided. The self-assembled layer of small molecules containing silyl groups, phosphate groups, and thiol groups can form a dense buffer layer, and the variable modification of groups can play a guiding role for the molecular arrangement and stacking of organic semiconductor materials with different structures. The dielectric polymers as growth-assisted layer have good compatibility with organic semiconductors. It is easy to obtain high-quality interface of growth-assisted layer with convenient prepared dielectric polymers. Also, the interface chemical properties can be adjusted by modifying the side groups of the polymer.

In some embodiments, the core of the material of the organic single-crystalline semiconductor thin film contains a π-conjugated structure, with a band gap width ≤3.5 eV. Preferably, the organic semiconductor material is small organic semiconductor molecules; more preferably, the small organic semiconductor molecules are selected from any one of linear acenes, linear heteroacenes, benzothiophene, perylene, diphenylanthracene, fullerene and their respective derivatives.

The small molecules of organic semiconductors refer to the organic semiconductor material with a fixed molecular weight and a well-defined molecular structure. The width of band gap is the energy difference between the top of the valence band and the bottom of the conduction band in insulators and semiconductors, also known as the forbidden bandwidth. The π-conjugated system refers to a system wherein conjugated π bonds are able to form. Proper band gap width ensures the display of intrinsic characteristics of organic semiconductors and the tailoring of field-effect can be realized. The core of linear acenes, linear heteroacenes, benzothiophene, perylene, diphenylanthracene, fullerene and their respective derivatives contains π-conjugated structure, high-quality organic single-crystalline semiconductor thin film could be easily obtained due to their good crystallinity. For example, 6,13-bis(triisopropylsilylethynyl)pentacene (TIPS-pentacene) and 2,7-dioctyl[1]benzothieno[3,2-b][1] benzothiophene (C₈—BTBT) have a certain length of silane chain or alkane chain side groups, their solubility in organic solvents is good, which is conducive to the realization of complete/full coverage growth of organic single-crystalline semiconductor thin films.

In some embodiments, the organic semiconductor single crystal array is obtained by in-situ uniform growth crossing the electrodes. The organic semiconductor single crystal array provided by the present invention is directly in-situ grown via solution methods on a substrate with pre-deposited source/drain electrodes. The in-situ uniform growth crossing the electrodes means that the crystals constituting the organic semiconductor single crystal array grow uniformly before crossing the electrodes 100, at the electrode edges 101 and 103, on the electrodes 102 and after crossing the electrodes 104, so that the morphology of the organic semiconductor single crystal array keeps basically unchanged before crossing the electrodes 100, at the electrode edges 101 and 103, on the electrodes 102, and after crossing the electrode 104. Compared with transferring pre-grown organic semiconductor single crystals on source/drain electrodes as reported in the prior art, the in-situ growth of organic semiconductor single crystal array which crossing the electrodes has avoided the damage to organic semiconductor single crystals during transferring and the poor contact issue between the electrodes and organic semiconductor single crystals after transferring. The possibility of preparing an organic semiconductor single crystal array with sufficiently high effective coverage ratio or even complete/full coverage is greatly improved.

The second object of the present invention is to provide a field-effect transistor, the field-effect transistor comprises any form of organic single-crystalline semiconductor structure as described above. The field-effect transistor includes top-gate and bottom-gate devices. The gate and dielectric layer of the top-gate devices are located above the organic single-crystalline semiconductor structure. The gate and dielectric layer of the bottom-gate devices are located beneath the organic single-crystalline semiconductor structure.

In the field-effect transistor, when the voltage is applied, the electrodes in the organic single-crystalline semiconductor structure aforementioned can be divided into source electrodes and drain electrodes according to whether they are grounded or not. The source, drain and gate electrodes in the field-effect transistor are commonly used electrodes in semiconductor devices; the electrodes can be selected from metal or non-metal; the electrodes can be selected from the same kind or different kinds of metal/non-metal stacking together; preferably, the metal electrodes can be selected from platinum (Pt), gold (Au), silver (Ag), aluminum (Al), copper (Cu), calcium (Ca), chromium (Cr), the non-metal electrodes can be selected from silicon, graphene and its derivatives. Preferably, for p-type semiconductors, the source/drain electrodes are selected from metals whose work function differs from the HOMO energy level of the corresponding semiconductor layer by ≤0.5 eV, which is helpful to reduce the injection barrier, improve the transport performance of carriers, and reduce the threshold voltage as well as sub-threshold slope. More preferably, the source/drain electrodes are selected from metals with high affinity for the organic semiconductor layers and/or organic solvents. It helps to spread the organic solutions on the substrate for the solution-processed organic semiconductor layer. Here, the arrangement of organic molecules at the gas-liquid interface is easier to control, and it benefits the adsorption of organic semiconductor molecules on the metal electrodes to form a well-aligned organic semiconductor single crystal array.

The thickness of the source/drain electrodes is 0.1 nm to 100 nm; preferably, the thickness of the source/drain electrodes is 10 nm to 50 nm. If the source/drain electrodes are too thin, contact problems might occur for devices in TGBC structure, as a result, the transport performance of carrier decreases and the required turn-on voltage increases. If the source/drain electrodes are too thick, it will hinder the growth of crystals on the substrate with pre-deposited source/drain electrodes, which may result in discontinuity of the crystal arrays, deterioration of the crystal quality, and easy breakage of crystals, additionally, the processing costs are increased.

The type and thickness of the gate electrodes can be adjusted according to actual condition. The thickness of gate electrodes cannot be too thin, otherwise the surface of gate electrodes is easily damaged. Moreover, the dielectric layer (the gate insulating layer) of the devices in TGBC structure has certain roughness and undulations, which will result in failure for conducting of electrodes. In addition, in order to save production cycle and raw materials, the dielectric layer should not be too thick. The thickness of the dielectric layer is 10 nm to 100 nm. Preferably, the thickness of the dielectric layer is 20 nm to 50 nm.

The dielectric layer is an organic or inorganic molecular layer with dielectric properties; preferably, it can be selected from any one or more of polymethyl methacrylate, polyvinyl alcohol, polyvinyl acetate, polyimide, polyvinylidene fluoride, polyvinylidene fluoride copolymer, polyvinylidene fluoride-trifluoroethylene-chlorofluoroethylene, polystyrene, poly-α-methylstyrene, polyvinylpyrrolidone, polyvinylphenol, parylene, benzocyclobutene, perfluoro(1-butenyl vinyl ether) polymer and cyanoethyl propane stacking/overlapping together. In order to reduce the process steps and equipment cost, the selected dielectric layer can be prepared by a solution method, which has good solubility in an orthogonal solvent that does not dissolve the organic single-crystalline semiconductor layer.

It should be noted that in order to protect the organic single-crystalline semiconductor layer from damage during the preparation of the dielectric layer, the lamination of dielectric layer can be adopted. Thus, the first step is to prepare a thin insulating layer on the organic semiconductor single crystals as the first insulating layer for encapsulation/packaging to protect the crystals, then a thicker insulating layer could be deposited on the first insulating layer as the second insulating layer to realize the switching performance of organic field-effect transistors. The first insulating layer and the second insulating layer can be selected from different organic molecules with dielectric properties. Preferably, the thickness of the first insulating layer is 2 nm to 20 nm

The substrate of the field-effect transistor is selected from silicon substrates, metal oxide substrates, glass substrates, ceramic substrates, or commonly used organic flexible substrates; preferably, the organic flexible substrate could be selected from polyethylene naphthalate, polyethylene terephthalate, polyether ether ketone, polyimide, polycarbonate, polyether sulfone resin, polyarylene, and polycyclic olefin.

In some embodiments, the field-effect transistor also includes a buffer layer and/or an encapsulation layer.

The buffer layer includes various organic or inorganic thin films that improve the efficiency of injecting carriers from the electrodes into the semiconductor layer, which could modify the work function or surface energy of the electrode surface, thus the injection barrier and contact resistance could be effectively reduce. Moreover, the performance of carrier transportation in the devices could be improved, and the operating voltage is reduced. The modification of the source/drain electrodes can also improve the morphology of the organic semiconductor single crystal arrays on the electrode surface. Optional materials of buffer layer include transition metal oxides, metal halides, metal phthalocyanines, aromatic sulfur compounds, self-assembled auxiliary growth layers, 2,3,5,6-tetrafluoro-7,7′,8,8′-tetracyanodimethyl-p-benzoquinone, and conjugated polyelectrolyte.

The encapsulation layer includes various organic and inorganic thin films, which can block the active layer in the devices by oxygen, moisture or other impurities in the environment. To prevent the device's performance from aging too fast, the encapsulation layer is helpful for the device to work properly in a complex atmosphere. The optional materials of encapsulation layer include resin, high molecular polymer, and inorganic oxide and so on.

The third object of the present invention is to provide an optoelectronic device. The optoelectronic device includes the field-effect transistor above-mentioned. Preferably, the optoelectronic device is selected from the group consisting of light-emitting diodes, complementary circuits, displays, sensors, and memory devices.

The fourth object of the present invention is to provide an integrated optoelectronic device array. As shown in FIG. 7, the integrated optoelectronic device array is obtained by integrating one or more optoelectronic devices as described above in N dimensions, where N is a positive integer greater than or equal to 1. The integrated array of optoelectronic devices can be widely used in detectors, inverters, oscillators, and backplane circuitry of organic light-emitting diode displays and so on.

The fifth object of the present invention is to provide a method for preparing an organic single-crystalline semiconductor structure, which includes the following steps:

1) The growth-assistant layer and the electrodes are sequentially prepared on the substrate; preferably, the electrodes are in contact with the growth-assistant layer in an upper type and/or embedded type. The upper type means that the upper surface of the growth-assistant layer is in contact with the lower surface of the electrodes, and the embedded type means that the electrode is half-embed or penetrates the growth-assistant layer;

2) The organic semiconductor material is dissolved in an organic solvent to prepare an organic semiconductor solution;

3) Regulate the temperature and humidity of the growth environment to obtain a stable growth environment, the deviation of the ambient temperature is ≤±2° C., and the deviation of the ambient humidity is ≤±3%; preferably, the ambient temperature is 20° C. to 25° C.; preferably, the ambient humidity is ≤55%; and more preferably, the ambient humidity is ≤40%;

4) Adjust the gap distance between the shearing tool and the substrate that prepared in step (1), the gap distance is 50 μm to 300 μm; Preferably, the gap distance is 100 μm to 150 μm; besides, the deviation of the gap distance that between the lower surface of the shearing tool and the substrate ≤10 μm needs to be guaranteed, in order to obtain a stable storage space for solution. The solution storage space is the space formed between the lower surface of the shearing tool and the substrate. Preferably, the lower surface of the shearing tool is substantially parallel to the substrate;

5) The organic semiconductor solution prepared in step (2) is filled into the solution storage space prepared in step (4), and let it stand for 1 second to 30 seconds after the filling is completed;

6) Shear the organic semiconductor solution at a constant linear velocity under a constant shearing temperature in a constant direction from 100 to 104 to achieve organic single-crystalline semiconductor thin film on the substrates, wherein 100 represents before crossing the electrodes 104 represents after crossing the electrodes; the organic single-crystalline semiconductor thin film is composed of organic semiconductor single crystal arrays, and the morphology of organic semiconductor single crystal array keeps basically unchanged before crossing the electrode 100, at the electrode edges 101 and 103, on the electrode 102, and after crossing the electrode 104; the constant shearing temperature refers to the temperature deviation ≤±1° C. in the space including the substrate and the solution storage space; the constant linear velocity refers to the deviation of the linear velocity ≤±20 μm/s.

In some embodiments, the linear velocity is 1 μm/s to lcm/s; preferably, the linear velocity is 10 μm/s to 2 mm/s; more preferably, the linear velocity is 50 μm/s to 1 mm/s.

In some embodiments, the shearing temperature is 0° C. to 200° C.; preferably, the shearing temperature is 20° C. to 150° C.; more preferably, the shearing temperature is 30° C. to 100° C.

Since the growth of organic single crystals is extremely difficult to control, it is even more difficult to achieve uniform growth crossing the electrodes and complete/full coverage on substrates of arbitrary shape or arbitrary size. Organic single-crystalline semiconductor thin films with aforementioned morphology could only be obtained by combining the modification of organic semiconductor molecules from growth-assistant layer with careful control and integration on the growth conditions. The growth conditions include ambient temperature, ambient humidity, the gap distance between the shearing tool and the substrate, the standing nucleation time, whether it is completely filled, the shearing linear velocity and the shearing temperature.

In the step (1), the method for preparing the growth-assistant layer can be selected from the solution casting, spin-coating, solution shearing, solution dipping, and vapor phase self-assembly and so on. When solution method is adopted for preparing the growth-assistant layer, preferably, spin coating method is adopted, the surface roughness can be controlled by selecting suitable organic solvents and preparation temperature, and the hydrophilicity and hydrophobicity can also be tailored through surface treatment. The thickness and surface roughness of the deposited source/drain electrodes can be manipulated by evaporation rate and evaporation time. The electrodes in contact with the growth-assistant layer in an upper type can be realized by depositing the growth-assistant layer before the electrodes. By partially etching the growth-assistant layer using ultraviolet ozone/laser/plasma or other methods after depositing it and then depositing the electrodes in etched pits, the electrodes in contact with the growth-assistant layer in an embedded type can be achieved. When the growth-assistant layer is located above the electrodes, it will separate the organic semiconductor layer from the electrodes, so that carriers cannot be directly injected into the organic semiconductor layer from the electrodes because of the hindrance from the growth-assistant layer, resulting in device failure. Therefore, the location relationship that the growth-assistant layer beneath the electrodes or with the electrodes embedded can ensure the uniform growth of organic single-crystalline semiconductor thin film across the electrodes while maintaining the integrity of the organic semiconductor device function.

In the step (1), when preparing organic solutions, it is necessary to consider the effect on solvent evaporation rate. Preferably, an organic solvent with a higher boiling point and a π-conjugated structure is used to prepare the organic solution; as the most preferred, benzene solvents such as toluene, xylene, trimethylbenzene, chlorobenzene, dichlorobenzene, trichlorobenzene, decalin, tetrahydronaphthalene, and chlorinated naphthalene can be chosen for controlling the evaporation rate of the solution during the preparation of the organic single-crystalline semiconductor layer, therefore the control of the crystal morphology could be achieved. Multiple solvents could also be mixed to prepare the solution, so as to achieve more precise control over the polarity and evaporation rate of the solution. Organic semiconductor molecules need to be fully dissolved in organic solvents, for example, the organic semiconductor molecules can be sufficiently diffused and evenly distributed in the entire organic semiconductor solution by stirring overnight on a hot stage at 50° C. Insufficient dissolution will lead to too many heterogeneous nucleation sites, which will result in too small size of crystal grains, thereby the uniform growth of crystals crossing the electrodes cannot be achieved. On the other hand, the residue of solute aggregates is likely to be enclosed by the crystal during the crystal growth process, leading to non-uniform crystal morphology, and reducing the electrical performance of the obtained devices.

In order to obtain a stable growth environment, it is necessary to precisely control the ambient humidity and ambient temperature of the growth environment. Excessive humidity usually causes water molecules to be adsorbed on the surface of the growth-assistant layer and the electrodes. One result is to reduce the control of the growth-assistant layer on organic semiconductor molecules, because the growth interface is located on the surface of the growth-assistant layer and the electrodes. After completing the crystal growth, the growth interface is covered by the crystals, thereby it is difficult to remove the moisture. The second result is that the moisture acts as the trap for the electron transport of organic semiconductors, which greatly reduces the performance of electron transport in the devices, and even causes the deactivation of devices. Third, higher humidity affects the stability of the organic semiconductors. The ambient temperature of the growth environment will impact the evaporation rate of the organic solvents for the semiconductors as well as the gradient diffusion of solute concentration during the shearing process. Due to the organic single-crystalline semiconductor thin films obtained having a difference in thermal expansion coefficient with the substrate, too high or too low ambient temperature is prone to cause cracks in the organic semiconductor thin films.

The gap distance between the shearing tool and the substrate influences the amount of solution storage in it, and also affects the evaporation of the solution. If the gap distance is too large, the area of solution storage space exposed to the air will be so large that too fast solvent evaporation will be caused, thereby the greatly increased the crystallization rate might lead to disordered alignment/orientation of crystals during the growth process. On the other hand, less effective shearing from the shearing tool will occur at the bottom of the solution if the gap distance is too large. However, too small the gap distance will result in small solution storage space, thus enough solution cannot be stored, which destroys the continuity of the organic single-crystalline semiconductor thin film, eventually, the complete/full coverage is failed to achieve. Besides, the limit of solution storage space at the direction perpendicular to the substrate will lead to vertical spatial confinement. Here, the space for transforming from metastable polymorphs to equilibrium polymorphs is not enough, therefore, metastable polymorphs are presented in the organic single-crystalline semiconductor thin film, and the overall quality of thin films is damaged. The gap distance between the shearing tool and the substrate should be equal everywhere to ensure that the lower surface of the shearing tool is almost parallel to the substrate. If gap distance varies between the lower surface of shearing tool and the substrate (along the direction which is perpendicular to the shearing direction), the droplets in the solution storage area are likely to tilt toward the lower end due to the gravity, so that only partial substrate can be coated with the organic semiconductor solution. It is detrimental for attaining complete/full coverage of organic single-crystalline semiconductor thin films. Therefore, a suitable and constant gap distance is a prerequisite for achieving high-quality organic single-crystalline semiconductor thin films.

The organic semiconductor solution needs to slowly fill the entire solution storage space, the purpose is to ensure that the organic semiconductor solution can be effectively sheared by the shearing tool. Thus, the highly uniform morphology and thickness of the obtained organic single-crystalline semiconductor thin film could be guaranteed. When the filling speed is too fast, the droplets are easy to remain on the surface of the shearing tool, thus disturbance to the solution in the solution storage space might appear.

Making the organic semiconductor solution stand for a period in the solution storage space could lead to slow evaporation of partial solvents, a tiny amount of crystal nuclei will be formed, which is beneficial to continuous growth of p1D or p2D morphology for crystals initiating from the nucleation sites. The specific time of the standing can be manipulated according to the type of organic semiconductor molecules and the boiling point of the selected organic solvents.

The shearing needs to be carried out along a constant direction with a constant linear velocity and a constant shearing temperature. Also, the process of solution shearing needs to be performed within a suitable and constant shearing temperature range. The constant shearing temperature is to maintain the stability of the shearing temperature. The instability of shearing temperature will lead to disorder in the solution during the shearing process, and discontinuity and morphology change will appear in the thin films. The conditions of the shearing temperature could be adjusted according to the situations, since the shearing temperature is required to enable the shearing rate of the shearing tool to match the nucleation rate of the crystals. If the shearing temperature is too low, the solvent evaporation will be too slow during the shearing process, it does not only hinder the alignment of the single crystals obtained, but also reduce the effective charge transport in organic single-crystalline semiconductor layer. Too high shearing temperature will cause too fast solvent evaporation, thus the organic semiconductor molecules might remain for too long in the solution storage space formed between the underside of the shearing tool and the substrate, leading to discontinuity of the single crystals. At the same time, excessively high shearing temperature will implement cracks or other damages to the crystal film, which will reduce the performance of the devices. Constant linear velocity and shear direction could help to better control the growth orientation for organic semiconductor single crystals as well as morphology of the film. Constant orientation is applied on solution, which can achieve complete/full coverage of organic single-crystalline semiconductor thin films on a substrate of arbitrary shape or arbitrary size. Simultaneously, it can also realize unrestricted in-situ continuous growth of organic single-crystalline semiconductor thin films on a substrate of arbitrary shape or arbitrary size. That is, when the solution supply is sufficient, it is expected to obtain a continuous and uninterrupted growth of completely/fully covered organic single-crystalline semiconductor thin films. The relative linear velocity between the shearing tool and the substrate needs to be kept constant during the solution shearing process, in order to avoid the influence of fluctuations caused by the instability of the linear velocity on the morphology and quality of the crystal growth. Too low linear velocity leads to insufficient shearing effect on the solution, therefore, the crystal morphology cannot be well controlled, and disorderly alignment/orientation of crystals is prone to occur. If the linear velocity is too fast, the shearing effect on the solution will be too strong, as a result, excessively thin crystals will be obtained as well as increased roughness of crystal surface, ultimately, the decreased crystal quality hampers the normal operation of the devices.

The method for preparing organic single-crystalline semiconductor structure as described above has a low production cost and easiness to realize large-scale production, it is also convenient for combing with flexibility. Unexpected effects can be made using this method combined with the growth-assistant layer. With the solvent evaporation of the organic semiconductor solution, the solutes precipitate out, organic semiconductor molecules can realize well-aligned growth crossing the electrodes along the direction from 100 to 104 to under shearing force. The crystals are more inclined to precipitate at the contact interface between the organic semiconductor solution and the air due to the growth-assistant layer. The organic semiconductor molecules have received assistances from two directions. One is the interaction between the growth-assistant layer and organic semiconductor molecules and solvent molecules in the direction perpendicular to the growth interface, and the other is the shearing force of organic semiconductor molecules along the direction of crystal growth. The integration of two assistances aforementioned enables the organic single-crystalline semiconductor thin films to achieve uniform growth crossing the electrodes. In addition, this preparation method provides a uniform storage space for the organic semiconductor solution, and the preparation of organic semiconductor single-crystalline thin films which are fully covered on a substrate of arbitrary shape or arbitrary size can be achieved only using a very low volume of solution. With continuous supply of the solution, unrestricted in-situ growth of organic single-crystalline semiconductor thin films can be realized.

In some embodiments, the method for preparing the organic single-crystalline semiconductor structure also includes the step of further treatment for the organic single-crystalline semiconductor thin films after step (6); preferably, the further treatment is selected from any one or more of annealing, vacuum treatment, solvent annealing treatment, or surface treatment. And the surface treatment aforementioned is selected from any one or more of ultraviolet ozone treatment, plasma treatment, infrared light treatment, or laser etching.

For example, as for the annealing treatment, the obtained organic single-crystalline semiconductor thin film is placed on a hot stage, and the residual solvent molecules are removed by annealing treatment under a certain temperature for a certain time.

The further treatment could alter the molecular arrangement and molecular ordering in the crystals, thereby the crystal form could be changed, in some cases the quality of the obtained crystal could be improved, and the patterning of the organic single-crystalline semiconductor thin film is able to be realized.

The method for preparing the field-effect transistors further includes the steps of preparing gate electrodes and gate insulating layer in the method above-mentioned for preparing the organic single-crystalline semiconductor structures.

In some embodiments, the application of the organic single-crystalline semiconductor structures, the organic single-crystalline field-effect transistors, the optoelectronic devices, and the integrated arrays of optoelectronic devices in the fields of semiconductor devices, transportation logistics, mining, metallurgy, environment, medical equipment, explosion-proof testing, food, water treatment, pharmaceuticals, and biologicals.

The beneficial effects of the present disclosure are:

1) For the first time, an organic single-crystalline semiconductor thin film with uniform growth morphology crossing the electrodes is prepared by the present disclosure on the growth interface in bottom contact structure;

2) The effective coverage ratio of the organic single-crystalline semiconductor thin film is improved, while achieving high effective coverage ratio in both the lengthwise direction and the vertical direction, thereby the channels for carrier transport with maximized area are realized and the requirements of high-performance devices are satisfied;

3) The in-situ preparation of organic single-crystalline semiconductor thin films with as complete/full coverage as possible on bottom contact substrates of arbitrary shape or arbitrary size is realized, which overcomes the technical bias that completely/fully covered organic single-crystalline semiconductor thin films cannot be produced on bottom contact structure in theory;

4) A uniformly grown organic semiconductor single-crystalline thin film with complete/full coverage is obtained at the growth interface of the bottom contact structure. It combines the uniform growth, high effective coverage of the morphology and the single-crystalline state of the materials simultaneously, which satisfies the requirements for ideal devices;

5) A method that can realize industrialization and large-scale production is applied, and the growth of organic semiconductor single crystals is under control, eventually the organic single-crystalline semiconductor thin films with precisely controlled morphology are attained. Furthermore, the obtained organic semiconductor devices are able to achieve high-performance charge transport of carriers under normal operating voltage;

6) Unrestricted in-situ growth of organic single-crystalline semiconductor thin films is realized on bottom contact substrates of arbitrary shape or arbitrary size.

Currently, for organic semiconductor devices, obtaining the most ideal morphology of material (i.e., achieving an organic single-crystalline semiconductor thin film with the effective coverage ratio as large as possible and a uniformly grown morphology on a bottom contact substrate of arbitrary shape or arbitrary size) on the bottom contact structure is the biggest bottleneck for higher performance. The preparation method provided by the present invention overcomes technical bias and turns the preparation of ideal semiconductor devices into reality. The organic single-crystalline semiconductor thin films based on the method provided by the present invention have well-defined morphology, highly uniform thickness, as well as uniform alignment/orientation. And the thin films can grow uniformly crossing the electrodes, achieving complete/full coverage on bottom contact substrates of arbitrary shape or arbitrary size. The in-situ unrestricted growth can be realized, which is facile to produce on a large scale, and the prepared semiconductor devices are easy to integrate, which is beneficial for the realizing the industrialization.

### BRIEF DESCRIPTION OF THE DRAWINGS

FIG. 1A-FIG. 1C are a schematic diagram of the structure of a commonly used organic field-effect transistor device, FIG. 1A is the BGTC type, FIG. 1B is the bottom gate-bottom contact type, and FIG. 1C is the TGBC type.

FIG. 2 is a schematic diagram of working principles of the carrier injection and extraction for coplanar and staggered device structures. Gate dielectric is the gate insulating layer. CAZ refers to the carrier accumulation zone.

FIG. 3 is a schematic diagram of the resistance in a BGTC device and a TGBC structure device.

FIG. 4A-FIG. 4C are a schematic diagram of the organic single-crystalline semiconductor structure and the contact type of the growth-assistant layer and the electrodes of the present invention. FIG. 4A represents the upper type, FIG. 4B represents the half-embedding or penetrating in the embedded type, and FIG. 4C represents an organic single-crystalline semiconductor structure.

FIG. 5 is a schematic diagram of the array with linear-type arrangement of the present invention and a stereogram of an organic single-crystalline linear element, where a is the width of the linear element, b is the thickness of the linear element, c is the length of the linear element, and g is the width of the gap between the linear elements, c_{L1}, c_{L2}, . . . , c_{Lm} represent continuous lengths of crystals c_{L} in the 1, 2, . . . , m channels in m adjacent and continuous channels, respectively. And represent the contact widths k between the 1, 2, . . . , n crystals and source/drain electrodes, respectively, W represents width of channel, A represents the orientation angle.

FIG. 6 is a schematic diagram of the structure of the organic single-crystalline field-effect transistor of the present invention.

FIG. 7 is a schematic diagram of the effect of the integrated array of optoelectronic devices of the present invention.

FIG. 8 is an optical microscope image of the organic single-crystalline semiconductor structure of Example 1.

FIG. 9A is a schematic diagram of corresponding to the optical microscope image in FIG. 8, and FIG. 9B is a partial enlarged view within the dashed frame in FIG. 9A, which is a schematic diagram of uniform growth crossing the electrodes, FIG. 9C—FIG. 9H is a schematic diagram of non-uniform growth, where the organic single-crystalline semiconductor thin film grows crossing the electrodes along the crystal growth direction, 100 represents the area before crossing the electrode, 101 and 103 represent the area at the edges of the electrode, 102 represents the area on the electrode, 104 represents the area after crossing the electrode, and the area on the electrode refers to the area covered by the organic single-crystalline semiconductor thin films on the electrode.

FIGS. 10A-10F are cross-polarized optical microscope images showing the morphology change of the organic semiconductor single-crystalline thin films crossing the electrodes.

FIG. 11 is a cross-polarized optical microscope image of the organic single-crystalline semiconductor structure in Example 1.

FIG. 12 is an atomic force microscope image and corresponding height data analysis of the organic single-crystalline semiconductor structure in Example 1.

FIG. 13 is an optical microscope image of the organic single-crystalline semiconductor structure in Example 7.

FIG. 14 is an optical microscope image of the organic single-crystalline semiconductor structure in Comparative Example 1.

FIG. 15 is the typical transfer characteristics of several organic single-crystalline field-effect transistors in Example 4 under the operating voltage of V_{DS}=−60V, V_{G}=−60V, wherein V_{DS} is the source-drain voltage, and V_{G} is the gate voltage;

FIG. 16 is the typical transfer characteristics of several organic single-crystalline field-effect transistors in Example 7 under the operating voltage of V_{DS}=−60V, V_{G}=−60V.

FIG. 17 is an optical microscope image of the organic single-crystalline semiconductor structure in Comparative Example 2.

FIG. 18 is a schematic structural diagram of an organic single-crystalline field-effect transistor in Comparative Example 3.

FIG. 19 is the typical transfer characteristics of several organic single-crystalline field-effect transistors in Comparative Example 3 under the operating voltage of V_{DS}=−60V, V_{G}=−60V.

FIG. 20 is an optical microscope image of the organic single-crystalline semiconductor structure in Comparative Example 4.

FIG. 21 is an optical microscope image of the organic single-crystalline semiconductor structure in Comparative Example 5.

FIGS. 22A-22B are schematic diagrams of prior art, corresponding to FIG. 2 (d) and FIG. 4 (a) in W. Deng, W. Hu, and X Zhang, Materials Today, 24, 17 (2019), respectively.

### DETAILED DESCRIPTION OF THE EMBODIMENTS

The present disclosure is further described below with reference to the drawings and embodiments. It should be noted that the following embodiments are used to illustrate the present invention but not to limit the scope of the present invention. In addition, it should be understood that after reading the teachings of the present invention, those skilled in the art can make various changes or modifications to the present invention, and these equivalent forms also fall within the scope defined by the appended claims of this application.

The terms “upper”, “lower”, “left”, “right”, “vertical”, “parallel”, “inner”, “outer”, “before”, “after”, etc. indicate that the orientation or positional relationship is based on the orientation or positional relationship shown in the attached figures, and is only for the convenience of describing the present invention and simplifying the description, rather than indicating or implying that the pointed device or element must have a specific orientation/positional relationship or be constructed/operated in a specific direction/position, therefore, it cannot be understood as a limitation of the present invention.

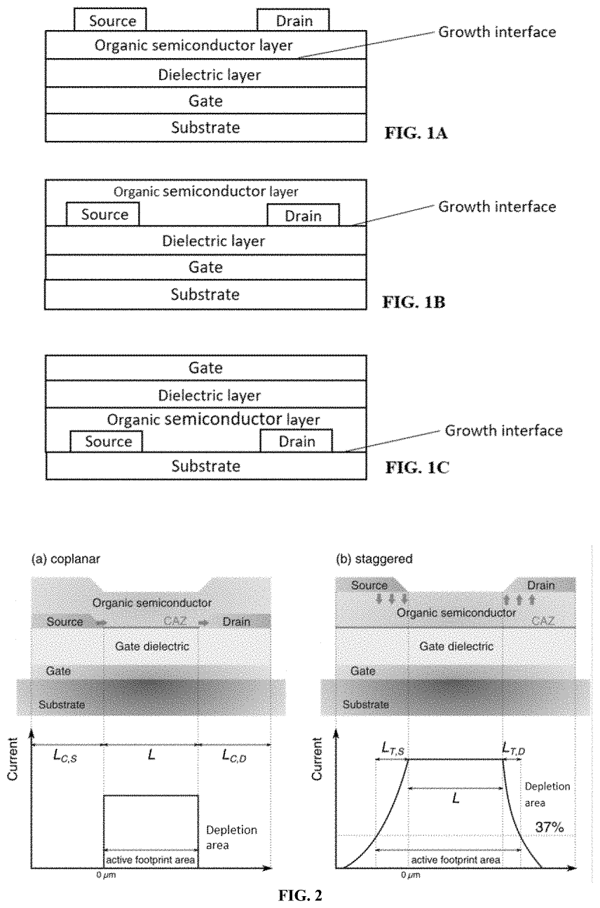

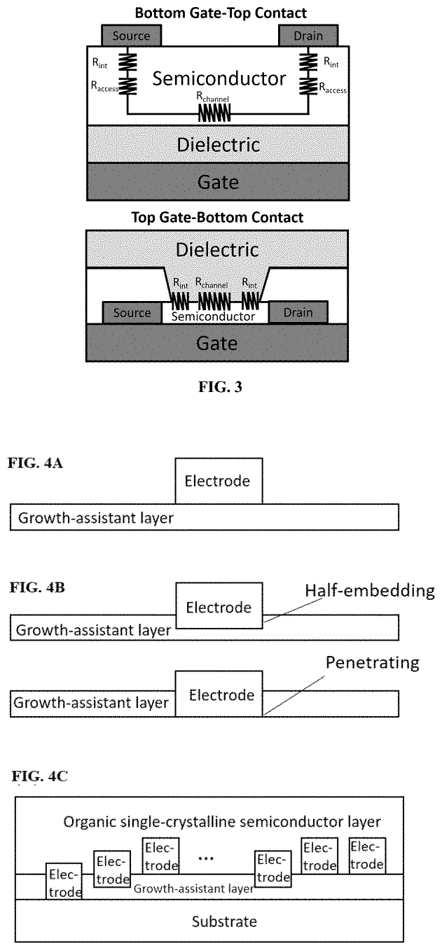

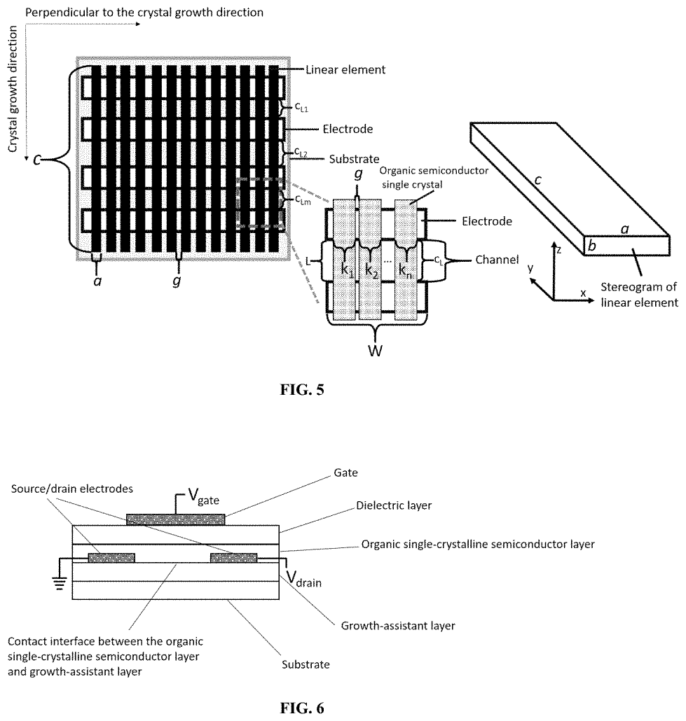

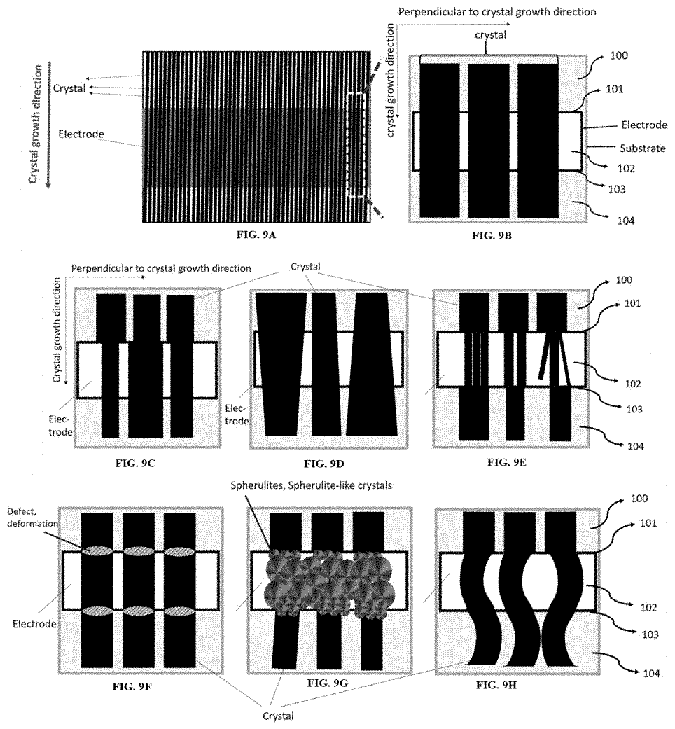

As shown in FIG. 1, an organic single-crystalline semiconductor structure is provided in the present invention, the structure comprises substrate, growth-assistant layer, electrodes and organic single-crystalline semiconductor layer. The last three are deposited sequentially from bottom to top on the substrate. The organic single-crystalline semiconductor layer aforementioned is grown on the growth-assistant layer and electrodes and is also in contact with them. The organic single-crystalline semiconductor layer is an in-situ uniformly grown organic semiconductor single-crystalline thin film crossing the electrodes, as shown in FIG. 8 and FIG. 9A-9B, and no obvious difference could be distinguished by the naked eye in the optical microscope image of the above-mentioned area. As shown in FIG. 5, FIG. 8, FIG. 9A-9B and FIG. 11, the organic single-crystalline semiconductor layer is organic single crystal arrays of small molecules with linear-type arrangement/orientation that can realize uniform growth crossing the electrodes. As displayed in FIG. 4, the growth-assistant layer is located underneath the electrodes, the electrodes are in contact with growth-assistant layer in an upper type and/or embedded type, the upper type refers to the upper surface of growth-assistant layer in contact with the lower surface of the electrodes, and the embedded type refers to the electrodes half-embedding or penetrating the growth-assistant layer. The electrodes are arranged on growth-assistant layer in either or both of the upper type and the embedded type.

In various embodiments, the organic semiconductor single-crystalline thin film is an organic semiconductor single crystal array composed of multiple crystals. For the description in this article, each separate and independent crystal in the organic semiconductor single-crystalline thin film is termed as linear element if it meets the following two characteristics simultaneously: 1) It can achieve uniform growth with basically unchanged morphology crossing the electrodes, as shown in FIG. 5, FIG. 8 and FIG. 9A-9B, wherein the black solid stripes represent crystals. That is, the morphology of the crystal keeps unchanged before crossing the electrode 100, at the electrode edges 101 and 103, on the electrode 102 and after crossing the electrode 104; 2) each crystal is single crystal. Preferably, the morphology of the linear element is pseudo 1D (p1D) or pseudo 2D (p2D), and the thickness is highly uniform. As shown in FIG. 5, when multiple linear elements are aligned in the same orientation along the growth direction of the crystal, it is called linear-type arrangement.

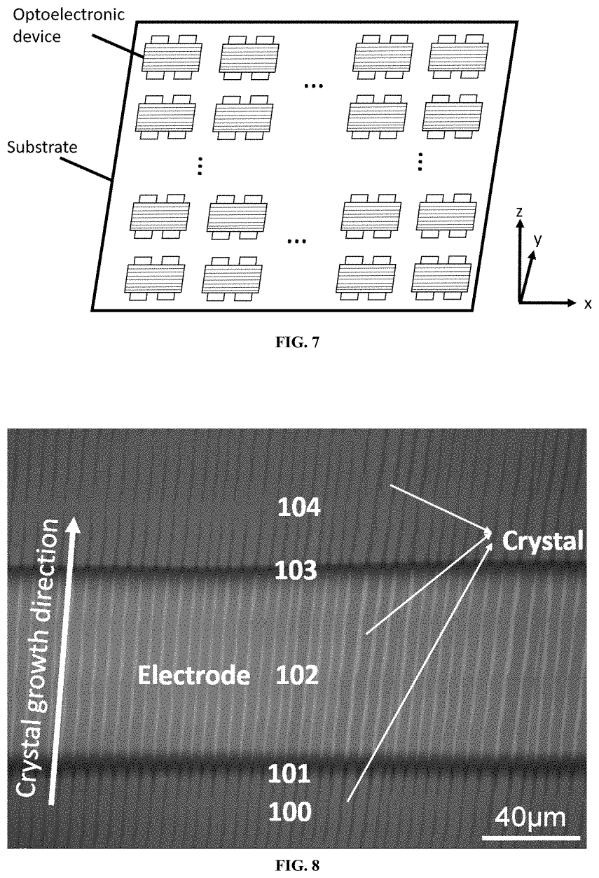

As shown in FIG. 6, on the basis of the above-mentioned organic single-crystalline semiconductor structure, the present invention also provides an organic single-crystalline field-effect transistor with a TGBC structure, containing the above-mentioned organic single-crystalline semiconductor structure, dielectric layer, and gate electrodes, and the last two parts are sequentially deposited on the surface of the organic single-crystalline semiconductor structure. As shown in FIG. 7, the optoelectronic device proposed by the present invention can also be integrated in one or more dimensions to obtain an integrated array of optoelectronic devices. The integrated array of optoelectronic devices can be widely used in detectors, inverters, oscillators, and backplane circuitry of organic light-emitting diode displays and so on.

The organic single-crystalline thin films can be detected by instruments that could analyze fine structures, such as optical microscope with crossed polarizers, atomic force microscope, scanning electron microscope, transmission electron microscope, laser confocal Raman spectrometer, single-crystal diffractometer, etc. The growth-assistant layer can be detected by instruments that can analyze the composition of elements, such as scanning electron microscope, transmission electron microscope, laser confocal Raman spectrometer, X-ray diffractometer, infrared spectrometer and so on. The structure of semiconductor devices can be inspected by optical microscope, atomic force microscope, scanning electron microscope, transmission electron microscope, etc. The related performance of semiconductor devices can be tested by instruments that can analyze the electrical/optoelectrical performance, such as semiconductor parameter analyzer, Hall effect testing instrument, scanning probe microscope, ferroelectric analyzer, quantum efficiency measurement system, transient spectrometer, solar cell I-V tester, optoelectronic detection system, micro-fluorescence spectrometer, spectrum analyzer, conductance measurement system and so on.

In order to characterize the morphology of organic single-crystalline semiconductor thin films, an optical microscope was used for observation. To characterize the quality of the organic single-crystalline semiconductor thin films provided by the present invention, a field-effect transistor with bottom contact structure was prepared based on the organic semiconductor structure aforementioned, and its field-effect behaviors were tested with a semiconductor parameter analyzer.

### Example 1

A bottom contact organic single-crystalline semiconductor structure based on 6,13-bis(triisopropylsilylethynyl) pentacene (TIPS-pentacene) and a preparation method for TGBC devices based on the structure, the following steps are included:

(1) Take a P-type <100> silicon wafer with a thickness of 575 with a 300 nm-thick silicon dioxide insulating layer on the silicon wafer, then spin-coat the crosslinked polystyrene on the substrate to prepare a growth-assistant layer;

(2) Deposit Au electrodes in long strip shape with a thickness of about 30 nm by thermal evaporation under high vacuum as the source/drain electrodes on the initial film prepared in step (1), and make the upper surface of the growth-assistant layer in contact with the lower surface of the electrodes as an upper type;

(3) Regulate the ambient temperature and ambient humidity of the growth environment at 20±1° C. and 40±2%, respectively;

(4) Adjust the gap distance between the shearing tool and the substrate prepared in step (1) to 150 and ensure that the gap distance between the lower surface of the shearing tool and the substrate is equal everywhere;

(5) Prepare 1 wt % TIPS-pentacene in mesitylene solution. After heating and stirring the solution to dissolve the solutes sufficiently, use a pipette tip to slowly fill the solution into the solution storage space, and let it stand for 10 s after the space is completely filled;

(6) Use a shearing tool to slowly and uniformly shear the solution slowly and uniformly in a constant direction from the 100 to 104 crossing the electrodes at a linear velocity of 400±5 μm/s under a temperature of 60° C. Subsequently, the organic single-crystalline semiconductor layer is heat-treated at 100° C. for 8 hours to remove excess solvents;

(7) Spin-coat a dielectric layer on the organic single-crystalline semiconductor layer and deposit the gate electrodes of Au with a thickness of about 50 nm by thermal evaporation under a high vacuum to obtain organic single-crystalline field-effect transistors.

The substrate can be selected from commonly used organic semiconductor device substrates. Further, the substrate can be a hard substrate, such as a silicon substrate (Si/SiO2), a metal oxide substrate (AlOx) and so on. And the substrate also could be a flexible polymer substrate, such as polyethylene terephthalate (PET), polyethylene naphthalate (PEN), polyimide (PI) and so on.

Use optical microscope and atomic force microscope to extract the fine structure and morphology information to characterize the structure and morphology of the obtained organic single-crystalline semiconductor thin films, and the electrical performance of field-effect transistors is characterized by semiconductor parameter analyzer which is capable of detecting the comprehensive electrical properties of various semiconductor devices and materials. According to the characterization results, the organic semiconductor single-crystalline thin films prepared in this embodiment is grown on both the growth-assistant layer and the electrodes. The organic single-crystalline semiconductor thin film is composed of organic semiconductor single crystal arrays. The morphology of organic semiconductor single crystal arrays keeps basically unchanged before crossing the electrode 100, at the electrode edges 101 and 103, on the electrode 102, and after crossing the electrode 104. The corresponding organic single-crystalline semiconductor structure satisfies the depositing order that the growth-assistant layer, the electrodes, and the organic single-crystalline semiconductor layer are deposited on the substrate sequentially from bottom to top.

### Example 2

A bottom contact organic single-crystalline semiconductor structure based on 6,13-bis(triisopropylsilylethynyl) pentacene (TIPS-pentacene) and a preparation method for TGBC devices based on the structure.

For the preparation method of the field-effect transistor device of the Example 2, refer to the Example 1, the formula and process parameters are shown in Table 1 and Table 2, respectively. The structure and performance characterization methods are the same as those in Example 1. The related device performance is shown in Table 4.

### Example 3

A bottom contact organic single-crystalline semiconductor structure based on 6,13-bis(triisopropylsilylethynyl) pentacene (TIPS-pentacene) and a preparation method for TGBC devices based on the structure.

For the preparation method of the field-effect transistor device of the Example 3, refer to the Example 1, the formula and process parameters are shown in Table 1 and Table 2, respectively. The structure and performance characterization methods are the same as those in Example 1. The related device performance is shown in Table 4.

### Example 4

A bottom contact organic single-crystalline semiconductor structure based on 6,13-bis(triisopropylsilylethynyl) pentacene (TIPS-pentacene) and a preparation method for TGBC devices based on the structure.

For the preparation method of the field-effect transistor device of the Example 4, refer to the Example 1, the formula and process parameters are shown in Table 1 and Table 2, respectively. The structure and performance characterization methods are the same as those in Example 1. The related device performance is shown in Table 4.

### Example 5

A bottom contact organic single-crystalline semiconductor structure based on 6,13-bis(triisopropylsilylethynyl) pentacene (TIPS-pentacene) and a preparation method for TGBC devices based on the structure.

For the preparation method of the field-effect transistor device of the Example 5, refer to the Example 1, the formula and process parameters are shown in Table 1 and Table 2, respectively. The structure and performance characterization methods are the same as those in Example 1. The related device performance is shown in Table 4.

### Example 6

A bottom contact organic single-crystalline semiconductor structure based on 6,13-bis(triisopropylsilylethynyl) pentacene (TIPS-pentacene) and a preparation method for TGBC devices based on the structure.

For the preparation method of the field-effect transistor device of the Example 6, refer to the Example 1, the formula and process parameters are shown in Table 1 and Table 2, respectively. The structure and performance characterization methods are the same as those in Example 1. The related device performance is shown in Table 4.

### Example 7

A bottom contact organic single-crystalline semiconductor structure based on 6,13-bis(triisopropylsilylethynyl) pentacene (TIPS-pentacene) and a preparation method for TGBC devices based on the structure.

For the preparation method of the field-effect transistor device of the Example 7, refer to the Example 1, the formula and process parameters are shown in Table 1 and Table 2, respectively. The structure and performance characterization methods are the same as those in Example 1. The related device performance is shown in Table 4.

### Example 8

A bottom contact organic single-crystalline semiconductor structure based on Rubrene and a preparation method thereof.

For the preparation method of organic single-crystalline semiconductor structure of the Example 8, refer to the step (1-6) in Example 1, the formula and process parameters are shown in Table 1 and Table 2, respectively. The structure characterization methods are the same as those in Example 1.

### Example 9

A bottom contact organic single-crystalline semiconductor structure based on 6,13-bis(triisopropylsilylethynyl) pentacene (TIPS-pentacene) and a preparation method thereof.

For the preparation method of organic single-crystalline semiconductor structure of the Example 9, refer to the step (1-6) in Example 1, the formula and process parameters are shown in Table 1 and Table 2, respectively. The structure characterization methods are the same as those in Example 1.

### Example 10

A bottom contact organic single-crystalline semiconductor structure based on 2,7-dioctyl[1]benzothieno[3,2-b]benzothiophene (C₈-BTBT) and a preparation method for TGBC devices based on the structure.

For the preparation method of the field-effect transistor device of the Example 10, refer to the Example 1, the formula and process parameters are shown in Table 1 and Table 2, respectively. The structure and performance characterization methods are the same as those in Example 1. The related device performance is shown in Table 4.

### Example 11

A bottom contact organic single-crystalline semiconductor structure based on 6,13-bis(triisopropylsilylethynyl) pentacene (TIPS-pentacene) and a preparation method thereof.

For the preparation method of organic single-crystalline semiconductor structure of the Example 11, refer to the step (1-6) in Example 1, the formula and process parameters are shown in Table 1 and Table 2, respectively. The structure characterization methods are the same as those in Example 1.

### Example 12

A bottom contact organic single-crystalline semiconductor structure based on 2,7-dioctyl[1]benzothieno[3,2-b]benzothiophene (C₈-BTBT) and a preparation method thereof.

For the preparation method of organic single-crystalline semiconductor structure of the Example 12, refer to the step (1-6) in Example 1, the formula and process parameters are shown in Table 1 and Table 2, respectively. The structure characterization methods are the same as those in Example 1.

### Example 13

A bottom contact organic single-crystalline semiconductor structure based on 2,7-dioctyl[1]benzothieno[3,2-b]benzothiophene (C₈-BTBT) and a preparation method thereof.

For the preparation method of organic single-crystalline semiconductor structure of the Example 13, refer to the step (1-6) in Example 1, the formula and process parameters are shown in Table 1 and Table 2, respectively. The structure characterization methods are the same as those in Example 1.

### Example 14

A bottom contact organic single-crystalline semiconductor structure based on 2,7-dioctyl[1]benzothieno[3,2-b]benzothiophene (C₈-BTBT) and a preparation method thereof.

For the preparation method of organic single-crystalline semiconductor structure of the Example 14, refer to the step (1-6) in Example 1, the formula and process parameters are shown in Table 1 and Table 2, respectively. The structure characterization methods are the same as those in Example 1.

### Example 15

A bottom contact organic single-crystalline semiconductor structure based on 2,7-dioctyl[1]benzothieno[3,2-b]benzothiophene (C₈-BTBT) and a preparation method thereof.

For the preparation method of organic single-crystalline semiconductor structure of the Example 15, refer to the step (1-6) in Example 1, the formula and process parameters are shown in Table 1 and Table 2, respectively. The structure characterization methods are the same as those in Example 1.

### Example 16

A bottom contact organic single-crystalline semiconductor structure based on 2,7-dioctyl[1]benzothieno[3,2-b]benzothiophene (C₈-BTBT) and a preparation method thereof.

For the preparation method of organic single-crystalline semiconductor structure of the Example 16, refer to the step (1-6) in Example 1, the formula and process parameters are shown in Table 1 and Table 2, respectively. The structure characterization methods are the same as those in Example 1.

### Example 17

A bottom contact organic single-crystalline semiconductor structure based on 6,13-bis(triisopropylsilylethynyl) pentacene (TIPS-pentacene) and a preparation method thereof.

For the preparation method of organic single-crystalline semiconductor structure of the Example 17, refer to the step (1-6) in Example 1, the formula and process parameters are shown in Table 1 and Table 2, respectively. The structure characterization methods are the same as those in Example 1.

### Example 18

A bottom contact organic single-crystalline semiconductor structure based on 6,13-bis(triisopropylsilylethynyl) pentacene (TIPS-pentacene) and a preparation method thereof.

For the preparation method of organic single-crystalline semiconductor structure of the Example 18, refer to the step (1-6) in Example 1, the formula and process parameters are shown in Table 1 and Table 2, respectively. The structure characterization methods are the same as those in Example 1.

### Example 19

A bottom contact organic single-crystalline semiconductor structure based on 2,8-difluoro-5,11-bis[2-(triethylsilyl)ethynyl]-anthradithiophene (diF-TES-ADT) and a preparation method for TGBC devices based on the structure.

For the preparation method of the field-effect transistor device of the Example 19, refer to the Example 1, the formula and process parameters are shown in Table 1 and Table 2, respectively. The structure and performance characterization methods are the same as those in Example 1. The related device performance is shown in Table 4.

### Example 20

A bottom contact organic single-crystalline semiconductor structure based on 2,8-difluoro-5,11-bis[2-(triethylsilyl)ethynyl]-anthradithiophene (diF-TES-ADT) and a preparation method thereof.

For the preparation method of organic single-crystalline semiconductor structure of the Example 20, refer to the step (1-6) in Example 1, the formula and process parameters are shown in Table 1 and Table 2, respectively. The structure characterization methods are the same as those in Example 1.

### Example 21

A bottom contact organic single-crystalline semiconductor structure based on 2,8-difluoro-5,11-bis[2-(triethylsilyl)ethynyl]-anthradithiophene (diF-TES-ADT) and a preparation method thereof.

For the preparation method of organic single-crystalline semiconductor structure of the Example 21, refer to the step (1-6) in Example 1, the formula and process parameters are shown in Table 1 and Table 2, respectively. The structure characterization methods are the same as those in Example 1.

### Example 22

A bottom contact organic single-crystalline semiconductor structure based on Perylene and a preparation method thereof.

For the preparation method of organic single-crystalline semiconductor structure of the Example 22, refer to the step (1-6) in Example 1, the formula and process parameters are shown in Table 1 and Table 2, respectively. The structure characterization methods are the same as those in Example 1.

### Example 23

A bottom contact organic single-crystalline semiconductor structure based on 9,10-diphenylanthracene (9,10-DPA) and a preparation method thereof.

For the preparation method of organic single-crystalline semiconductor structure of the Example 23, refer to the step (1-6) in Example 1, the formula and process parameters are shown in Table 1 and Table 2, respectively. The structure characterization methods are the same as those in Example 1.

### Example 24

A bottom contact organic single-crystalline semiconductor structure based on 6,13-bis(triisopropylsilylethynyl) pentacene (TIPS-pentacene) and a preparation method thereof.

For the preparation method of organic single-crystalline semiconductor structure of the Example 24, refer to the step (1-6) in Example 1, the formula and process parameters are shown in Table 1 and Table 2, respectively. The structure characterization methods are the same as those in Example 1.

### Comparative Example 1

A bottom contact organic single-crystalline semiconductor structure based on 6,13-bis(triisopropylsilylethynyl) pentacene (TIPS-pentacene) and a preparation method for TGBC devices based on the structure, the following steps are included:

(1) Take a PEN substrate with a thickness of 200 then deposit Au electrodes in long strip shape with a thickness of about 30 nm by thermal evaporation under high vacuum as the source/drain electrodes on the substrate;

(2) Regulate the ambient temperature and ambient humidity of the growth environment at 25±1° C. and 50±2%, respectively;

(3) Adjust the gap distance between the shearing tool and the substrate prepared in step (1) to 300 and ensure that the gap distance between the lower surface of the shearing tool and the substrate is equal everywhere;

(4) Prepare 1 wt % TIPS-pentacene in mesitylene solution. After heating and stirring the solution to dissolve sufficiently, use a pipette tip to slowly fill the solution into the solution storage space, and let it stand for 10 s after it is completely filled;

(5) Use a shearing tool to shear the solution slowly and uniformly in a constant direction from the 100 to 104 crossing the electrodes at a linear velocity of 400±10 μm/s under a temperature of 60° C. Subsequently, the organic single-crystalline semiconductor layer is heat-treated at 100° C. for 8 hours to remove excess solvents;

(6) Spin-coat a dielectric layer on the organic single-crystalline semiconductor layer and deposit the gate electrodes of Au with a thickness of about 50 nm by thermal evaporation under a high vacuum to obtain organic single-crystalline field-effect transistors.

The structure and device performance characterization method of Comparative Example 1 are the same as those methods in Example 1.

### Comparative Example 2

A bottom contact organic single-crystalline semiconductor structure based on 6,13-bis(triisopropylsilylethynyl) pentacene (TIPS-pentacene) and a preparation method for TGBC devices based on the structure, the following steps are included:

(1) Take a P-type <100> silicon wafer with a thickness of 575 with a 300 nm-thick silicon dioxide insulating layer on the silicon wafer, then spin-coat the crosslinked polystyrene on the substrate to prepare a growth-assistant layer;

(2) Deposit Au electrodes in long strip shape with a thickness of about 30 nm by thermal evaporation under high vacuum as the source/drain electrodes on the initial film prepared in step (1), and make the upper surface of the growth-assistant layer in contact with the lower surface of the electrodes as an upper type;

(3) Regulate the ambient temperature and ambient humidity of the growth environment at 20±1° C. and 50±2%, respectively;

(4) Prepare 0.1 wt % TIPS-pentacene in mesitylene solution. After it is fully dissolved, use the droplet-pinned crystallization method (DPC) at a temperature of 60° C. on the substrate prepared in step (2). Subsequently, the organic single-crystalline semiconductor layer is heat-treated at 100° C. for 8 hours to remove excess solvents;

(5) Spin-coat a dielectric layer on the organic single-crystalline semiconductor layer and deposit the gate electrodes of Au with a thickness of about 50 nm by thermal evaporation under a high vacuum to obtain organic single-crystalline field-effect transistors.

The structure and device performance characterization method of Comparative Example 2 are the same as those methods in Example 1.

### Comparative Example 3

A preparation method for BGTC devices based on 6,13-bis(triisopropylsilylethynyl) pentacene (TIPS-pentacene), the following steps are included:

(1) Take a P-type <100> silicon wafer with a thickness of 575 with a 300 nm-thick silicon dioxide insulating layer on the silicon wafer, then spin-coat the crosslinked polystyrene on the substrate to prepare an growth-assistant layer;

(2) Regulate the ambient temperature and ambient humidity of the growth environment at 20±1° C. and 50±2%, respectively;

(3) Adjust the gap distance between the shearing tool and the substrate prepared in step (1) to 150 and ensure that the gap distance between the lower surface of the shearing tool and the substrate is equal everywhere;

(4) Prepare 1 wt % TIPS-pentacene in mesitylene solution. After sufficiently dissolving the solutes in the solution, use a shearing tool to shear the solution slowly and uniformly in a constant direction from the 100 to 104 crossing the electrodes on the substrate prepared in step (1) at a linear velocity of 400±10 μm/s under a temperature of 60° C. Subsequently, the organic single-crystalline semiconductor layer is heat-treated at 100° C. for 8 hours to remove excess solvents;

(5) Spin-coat a dielectric layer on the organic single-crystalline semiconductor layer and deposit the source/drain electrodes of Au with a thickness of about 50 nm by thermal evaporation under a high vacuum to obtain organic single-crystalline field-effect transistors.

The structure and device performance characterization method of Comparative Example 3 are the same as those methods in Example 1.

### Comparative Example 4

A bottom contact organic single-crystalline semiconductor structure based on 6,13-bis(triisopropylsilylethynyl) pentacene (TIPS-pentacene) and a preparation method thereof.

For the preparation method of organic single-crystalline semiconductor structure of the Comparative Example 4, refer to the step (1-6) in Example 1, the formula and process parameters are shown in Table 1 and Table 2, respectively. The structure characterization methods are the same as those in Example 1.

### Comparative Example 5

A bottom contact organic single-crystalline semiconductor structure based on 6,13-bis(triisopropylsilylethynyl) pentacene (TIPS-pentacene) and a preparation method thereof.

For the preparation method of organic single-crystalline semiconductor structure of the Comparative Example 5, refer to the step (1-6) in Example 1, the formula and process parameters are shown in Table 1 and Table 2, respectively. The structure characterization methods are the same as those in Example 1.

### Comparative Example 6

A bottom contact organic single-crystalline semiconductor structure based on 6,13-bis(triisopropylsilylethynyl) pentacene (TIPS-pentacene) and a preparation method thereof.

For the preparation method of organic single-crystalline semiconductor structure of the Comparative Example 6, refer to the step (1-6) in Example 1, the formula and process parameters are shown in Table 1 and Table 2, respectively. The structure characterization methods are the same as those in Example 1.

### Comparative Example 7

A bottom contact organic single-crystalline semiconductor structure based on 6,13-bis(triisopropylsilylethynyl) pentacene (TIPS-pentacene) and a preparation method thereof.

For the preparation method of organic single-crystalline semiconductor structure of the Comparative Example 7, refer to the step (1-6) in Example 1, the formula and process parameters are shown in Table 1 and Table 2, respectively. The structure characterization methods are the same as those in Example 1.

### Comparative Example 8

A bottom contact organic single-crystalline semiconductor structure based on 6,13-bis(triisopropylsilylethynyl) pentacene (TIPS-pentacene) and a preparation method thereof.

For the preparation method of organic single-crystalline semiconductor structure of the Comparative Example 8, refer to the step (1-6) in Example 1, the formula and process parameters are shown in Table 1 and Table 2, respectively. The structure characterization methods are the same as those in Example 1.

### Comparative Example 9

A bottom contact organic single-crystalline semiconductor structure based on 6,13-bis(triisopropylsilylethynyl) pentacene (TIPS-pentacene) and a preparation method thereof.

For the preparation method of organic single-crystalline semiconductor structure of the Comparative Example 9, refer to the step (1-6) in Example 1, the formula and process parameters are shown in Table 1 and Table 2, respectively. The structure characterization methods are the same as those in Example 1.

### Comparative Example 10

A preparation method for bottom contact devices based on 6,13-bis(triisopropylsilylethynyl) pentacene (TIPS-pentacene), the following steps are included:

(1) Take a P-type <100> silicon wafer with a thickness of 575 with a 300 nm-thick silicon dioxide insulating layer on the silicon wafer;

(2) Deposit Au electrodes in long strip shape with a thickness of about 30 nm by thermal evaporation under high vacuum as the source/drain electrodes on the initial film prepared in step (1), and make the upper surface of the growth-assistant layer in contact with the lower surface of the electrodes as an upper type;

(3) Regulate the ambient temperature and ambient humidity of the growth environment at 25±1° C. and 40±2%, respectively;

(4) Adjust the gap distance between the shearing tool and the substrate prepared in step (1) to 250 and ensure that the gap distance between the lower surface of the shearing tool and the substrate is equal everywhere;

(5) Prepare 5 wt % TIPS-pentacene: PS=1:1 in mesitylene solution. After sufficiently dissolving the solutes in the solution, use a shearing tool to shear the solution slowly and uniformly in a constant direction from the 100 to 104 crossing the electrodes on the substrate prepared in step (1) at a linear velocity of 400±10 μm/s under a temperature of 60° C. Subsequently, the organic semiconductor layer is heat-treated at 100° C. for 8 hours to remove excess solvents.

The structure and device performance characterization method of Comparative Example 10 are the same as those methods in Example 1 Comparative Example 11:

A preparation method for bottom contact devices based on 6,13-bis(triisopropylsilylethynyl) pentacene (TIPS-pentacene), the following steps are included:

(1) Prepare 1 wt % TIPS-pentacene in mesitylene solution. After sufficiently dissolving the solutes in the solution, use drop-casting method to deposit organic single-crystalline semiconductor thin films on the silicon wafer;

(2) Cast a PDMS film on the organic single-crystalline semiconductor thin film prepared in step (1), after baking it at 60° C. for 2 h, let it stand for 12 h;

(3) Tear off the PDMS film, and transfer the organic semiconductor single crystals on the PDMS film to a silicon substrate with pre-deposited long strips of Au with a thickness of about 30 nm as source/drain electrodes under high vacuum.

The structure and device performance characterization method of Comparative Example 11 are the same as those methods in Example 1.

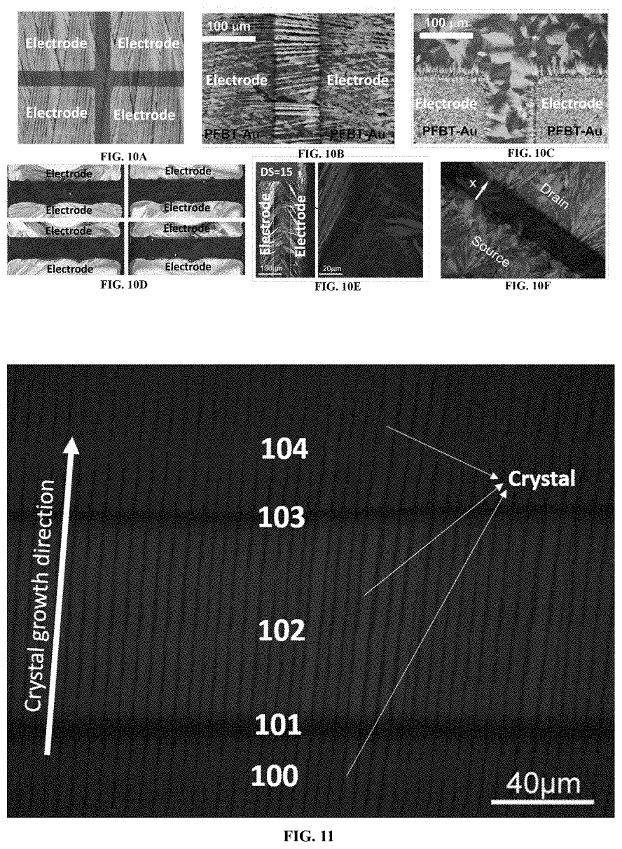

The morphology of the organic single-crystalline semiconductor layers obtained in Examples 1-24 and Comparative Examples 1-11 were characterized by cross-polarized optical microscope and atomic force microscope, and the performance of the related device was tested by a semiconductor parameter analyzer. Optical microscopy is a simple and effective method for observing the morphology of organic single-crystalline semiconductor thin films. Organic single crystals are anisotropic due to the highly ordered intrinsic structure with periodical molecular ordering. Under the orthogonal linearly polarized light of optical microscope, the object with anisotropy will exhibit the birefringence behavior. When the crystal growth direction is parallel or perpendicular to the polarization angle, the image can be used to determine whether the crystal axis in the field of view is highly oriented by observing whether uniform color and light-dark changes occur. This method could be applied to confirm the single-crystallinity (A. Yamamura et al., Science Advances, 4, eaao5758, (2018)). In the cross-polarized optical microscopic image, if the color or gray scale is non-uniform or the color changes, it indicates that the obtained crystal is not a single crystal; for example, as shown in FIG. 10B-10F, different shades of color can be observed in the organic semiconductor layer, the color or gray scale is non-uniform, indicating that the organic semiconductor layer is polycrystalline. If the color or gray scale of the crystal is basically uniform, indicating that the crystal is single-crystalline (for example, as shown in FIG. 11, the color or gray scale of each crystal is basically uniform, and the color or gray scale between different crystals is also basically the same, indicating that a typical organic single-crystalline thin film is obtained). Table 3 shows the morphology parameters of the organic single-crystalline semiconductor structures obtained in Examples 1-24 and Comparative Examples 2-4.

FIG. 8 and FIG. 11 are an optical microscopic image and a cross-polarized optical microscopic image both at 50× magnification of an organic single-crystalline field-effect transistor prepared in Example 1, respectively. The arrow in FIG. 8 represents the direction of crystal growth, and the horizontal strips in the middle part are deposited electrodes, the parts above and below the electrodes are channels, the vertical strips along the crystal growth direction are crystals obtained. The ribbon-shaped single crystals of TIPS-pentacene with well-aligned arrangement/orientation could be observed both in the channels and on the electrodes. And each crystal is linear shape under the observation from the top view. In the optical microscopic image of FIG. 8 and the corresponding cross-polarized optical microscopic image of FIG. 11, no obvious difference can be noticed in the morphology of the crystals between the electrodes and the channels. That is, during the in-situ growth of the crystals, the morphology keeps unchanged before crossing the electrode 100, at the electrode edges 101 and 103, on the electrode 102, and after crossing the electrode 104. The schematic diagram is shown in FIG. 9A, which displays that an organic semiconductor single-crystalline thin film with in-situ uniform growth crossing the electrodes has been prepared. As shown in FIG. 11, the organic semiconductor single-crystalline thin film obtained in Example 1 shows uniform color and brightness in the cross-polarized mode, indicating that the aligned crystals are single-crystalline. Each discrete crystal obtained satisfies the two requirements of the linear element, which proves that the linear elements are obtained. The contact angle between the growth-assistant layer and water of each example is shown in Table 4. Example 1 selected crosslinked polystyrene as the growth-assistant layer, which contains π-conjugated structure, and its water contact angle CA_{water}>90°. The interaction exists between this growth-assistant layer and TIPS-pentacene due to the 5 benzene rings in the core of TIPS-pentacene. Therefore, the impact to TIPS-pentacene crystals from the height of the electrodes during the growth has been greatly reduced, and the crystal does not break at the junction of the channel and the electrode. Moreover, there is no fracture of the TIPS-pentacene crystals to be observed at the contact area between the channels and the electrodes. The uniform growth crossing the electrodes lead to the crystals exhibiting no grain boundary where they encounter the electrodes, thereby the effective charge transport of carriers is guaranteed.

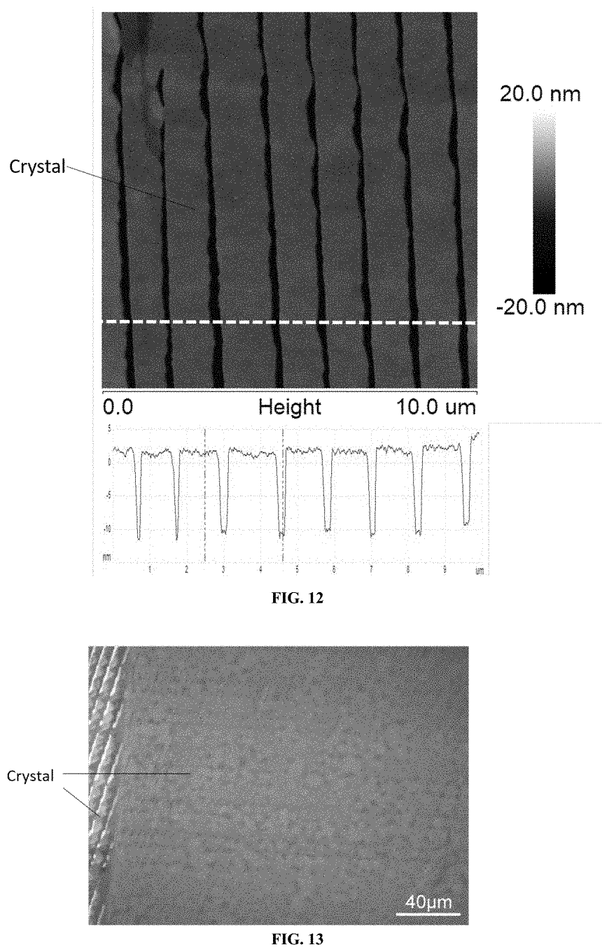

As shown in FIG. 8, the orientations of the organic single-crystalline semiconductor thin films are consistent, the orientation angle A formed between each crystal and the crystal growth direction could be calculated via using softwares that can analyze image pixels (such as Image J software, Matlab, Photoshop, Adobe Illustrator, etc., the present invention takes Image J software as an example). Taking 10 randomly selected crystals as an example (1.336°, 3.547°, 1.119°, 2.770°, 2.406°, 2.392°, 2.915°, 2.840°, 3.925°, 3.195°), the average orientation angle Ā is 2.645°, and the degree of orientation F=0.997, which indicates a good orientation degree. In addition, the color of crystals is basically uniform, indicating that the thickness of the organic semiconductor single-crystalline thin film is basically uniform. The width of the crystal and the size of the gap between the crystals are basically uniform, which further shows that the morphology of the crystals is precisely controlled under the shearing action of the shearing tool, the linear-type arrangement of crystals is realized on the bottom contact electrodes. FIG. 12 is an image of the morphology of the crystalline thin film in Example 1, which is characterized by an atomic force microscope after being processed by a software with an image processing function (for example, NanoScope Analysis, Matlab, etc., the present invention takes NanoScope Analysis software as an example), which further illustrates that the width of the crystals in the transverse direction and the thickness in the longitudinal direction are highly uniform (the thickness b of the crystal is 12.8 nm, 12.2 nm, 12.1 nm, 12.7 nm, 12.7 nm, 12.3 nm, 12.4 nm, 12.4 nm, the average thickness b is 12.45 nm, the standard deviation is 0.24 nm, and the coefficient of variation is 0.24/12.45*100%=1.92%). It can be deduced that the linear elements are well-aligned, which proves that an organic single-crystalline semiconductor thin film with linear-type arrangement is obtained.

Additionally, the morphologies of the organic single-crystalline semiconductor thin films obtained in Examples 2-6 and Examples 8-24 are similar to those in FIG. 8, only the crystal thickness b and width a slightly change. FIG. 13 is a cross-polarized optical microscopic image at 50× magnification of an organic single-crystalline field-effect transistor prepared in Example 7, the gray part is the substrate. The consistent growth of crystals on the substrate and the electrodes could also be observed. The crystal morphology is p1D and crystals are in ribbon-like shape. The gaps between the crystals are too small in the channels to be distinguished with the naked eye. In FIG. 8, FIG. 9A-9B and FIG. 11-13, it can be observed that the coverage area of the crystals in the channels is large while the gap between the crystals is small. Through Image J software analysis and calculation, the effective coverage ratio f_{cr} in the lengthwise direction of the organic single-crystalline semiconductor thin film of Example 1 is 100% (f_{cr}=(c_{L1}±c_{L2}+ . . . +c_{L5})/(L₁+L₂+ . . . +L₅)−(101.2 μm+98.7 μm+99.5 μm+104.1 μm+108.7 μm)/(101.2 μm+98.7 μm+99.5 μm+104.1 μm+108.7 μm)=100%). And the effective coverage ratio f_{cp} in the vertical direction is 79.88% (f_{cp}=(k₁+k₂+ . . . +k₄₆) W=(3.8 μm+3.3 μm+3.6 μm+4.1 μm+4.4 μm+4.6 μm+3.8 μm+4.1 μm+3.8 μm+3.6 μm+3.6 μm+3.3 μm+3.6 μm+2.8 μm+3.3 μm+3.8 μm+4.1 μm+4.9 μm+4.1 μm+3.8 μm+4.1 μm+3.8 μm+3.6 μm+2.6 μm+4.4 μm+4.4 μm+4.6 μm+3.6 μm+3.3 μm+4.6 μm+3.6 μm+4.4 μm+3.1 μm+4.4 μm+4.9 μm+4.1 μm+4.9 μm+4.6 μm+6.4 μm+5.4 μm+4.6 μm+3.6 μm+4.6 μm+4.4 μm+3.8 μm+4.6 μm)/234.2 μm=79.88%). The gap g is about 0.72 μm. Therefore, the complete/full coverage of the organic single-crystalline thin film is achieved. The width change R before and after the crystal crossing the electrodes is <5%. The length c of the crystal is in the order of ten millimeters, and the width a of the crystal is several microns. Combined with the crystal thickness measured by the atomic force microscope in FIG. 11, the thickness b of the crystal is a dozen nanometers, obviously, c/a>500, c/b>500 can be obtained, which indicates a typical p1D morphology.

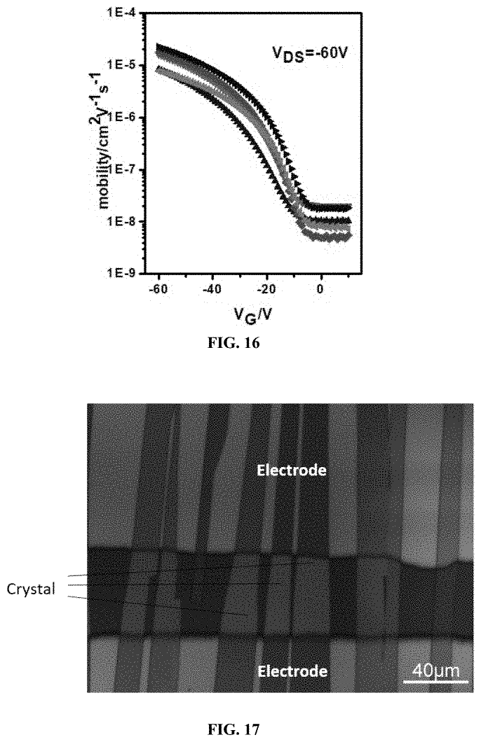

For the organic field-effect transistors prepared in Examples 1-5, Example 7, Example 10, Example 19, and Comparative Examples 3-4, and Comparative Examples 10-11, the gate electrode is connected to a negative voltage, the source is grounded, and the drain is connected to a negative voltage. The transfer characteristics of the devices are tested under V_{DS}=−60V, V_{G}=−60V, the calculated mobilities and threshold voltages in the saturation region are shown in Table 5. The hole mobility is a type of parameter for the carrier mobility. The higher the value of hole mobility, the faster the charge transport, and the higher the performance of the device. The smaller the absolute value of the threshold voltage normally means that the contact resistance is smaller, and the loss of operating voltage is less, ultimately, the working mode of the device is closer to the ideal state. It can be deduced from Table 5 that the flexible organic single-crystalline field-effect transistor prepared in Example 7 has the highest mobility. The linear velocity and shearing temperature in solution shearing have a greater impact on the performance of the devices. The organic single-crystalline field-effect transistor prepared by the linear velocity and shearing temperature selected in Example 4 has the best performance on the inorganic substrates. Several typical transfer curves in the organic single-crystalline field-effect transistors prepared in Example 4 are shown in FIG. 15, exhibiting uniform performance. Several typical transfer curves in the organic single-crystalline field-effect transistors prepared in Example 7 are shown in FIG. 16. Both FIG. 15 and FIG. 16 illustrate that the organic single-crystalline field-effect transistors prepared by the method of present invention have excellent device performance.

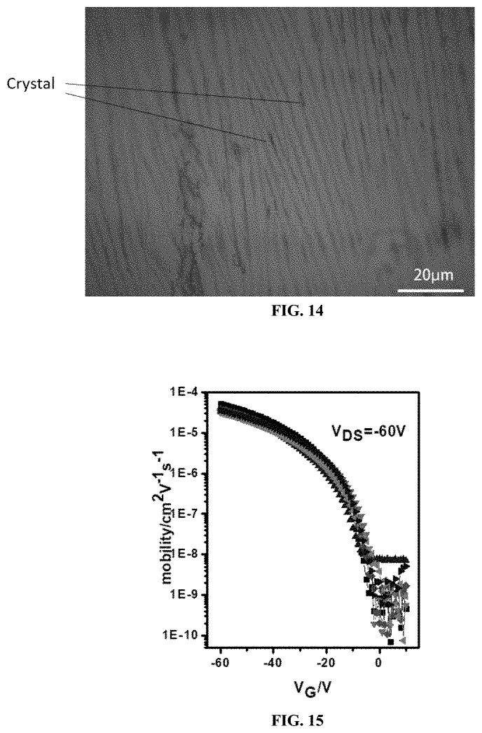

In order to illustrate the influence of the growth-assistant layer on the crystal morphology of the organic single-crystalline field-effect transistor in the TGBC structure, Comparative Example 1 uses the same operation process of Example 7 to prepare a device without the growth-assistant layer. The crystal morphology obtained in Comparative Example 1 is shown in FIG. 14. It can be observed that the crystal cannot grow continuously on the unmodified substrate, the crystal morphology is irregular with branching. Additionally, the width of the crystals is non-uniform. The performance of related field-effect transistor is unable to measure. It explains the necessity of the growth-assistant layer for the growth of organic semiconductor single-crystalline thin films in devices with the TGBC structure.

In order to illustrate the advantages of the preparation method provided by the present invention, Comparative Example 2 uses the existing technology according to the literature (H. Li et al., Advanced Materials, 24, 2588 (2012)) to prepare the devices by the droplet-pinned crystallization method (DPC). The crystal morphology is shown in FIG. 17. The degree of orientation of the crystals decreases without external shearing force, and non-uniform color is showed in the crystal, which elucidates that precise control of thickness in the organic single-crystalline semiconductor layer using the DPC method cannot be achieved. Besides, the effective coverage ratio in the channel is greatly reduced (approximately 50%) although the width of the crystal is larger. The degree of orientation in crystals is also greatly reduced, and the crystal shape is irregular with branching, moreover, the width change |R| is very obvious (|R|=28%), and the performance of the device based on the organic single-crystalline semiconductor thin film is shown in Table 5, which is inferior to Example 1. The hole mobility is only 0.34 cm² V⁻¹ s⁻¹, and the threshold voltage becomes larger, showing that irregular crystal morphology and low effective coverage ratio will reduce the device performance.

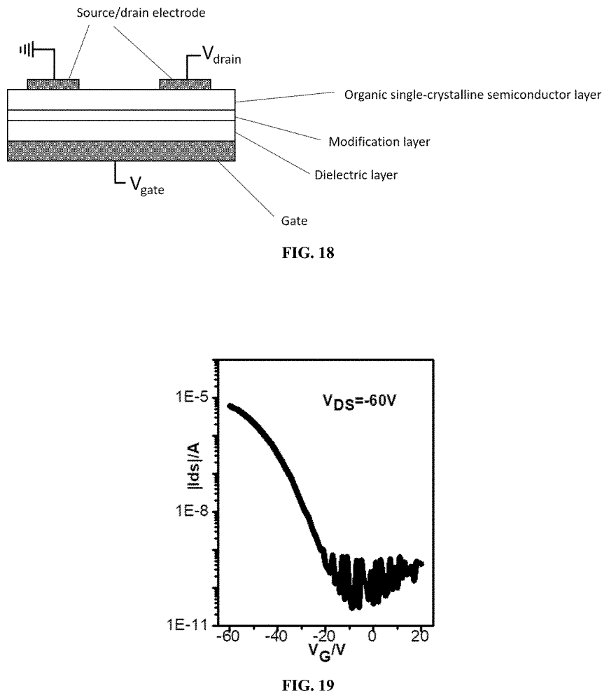

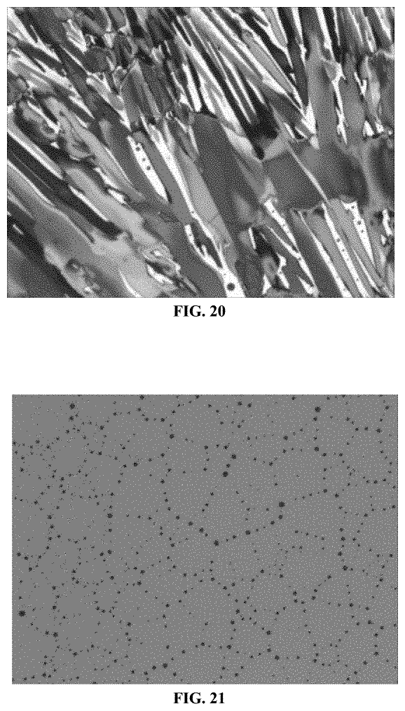

In order to illustrate the influence of the device structure, the same solution shearing linear velocity and shearing temperature as in Example 2 were used to prepare a BGTC organic single-crystalline field-effect transistor in Comparative Example 3. The device structure of Comparative Example 3 is shown in FIG. 18, and in FIG. 19 a typical transfer curve of the organic single-crystalline field-effect transistor prepared in Comparative Example 3 is displayed. According to the results in Table 5, compared with Example 2, the threshold voltage is greatly increased, which is not good for the working conditions of the devices. It could be ascribed to the heat damage on the crystal surface during the evaporation of source/drain electrodes. Thus, the advantages and practicality of organic single-crystalline semiconductor devices with TGBC structure are clearly explained.

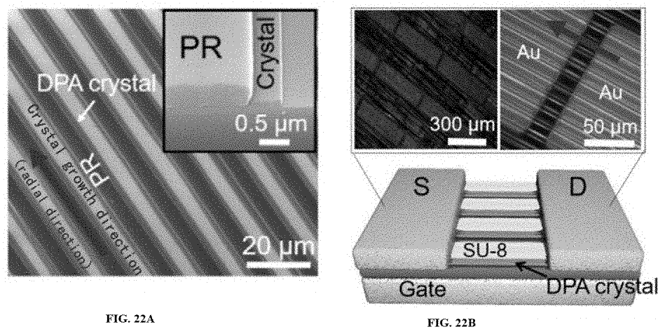

In order to illustrate the necessity of precise control of various conditions in the preparation method, the same organic semiconductor small molecules, solvents, and linear velocity and shearing temperature in solution shearing as in Example 1 were used in Comparative Examples 4-8. However, the obtained film morphology is shown in FIG. 20 and FIG. 21, respectively. The uniform growth of the organic semiconductor single-crystalline film is not obtained, because the non-ideal control of linear velocity stability (the linear velocity is not constant in Comparative Example 4), ambient humidity (the ambient humidity in Comparative Example 6 is too high), ambient temperature (the ambient temperature in Comparative Example 7 is too high and the temperature is not constant), the gap distance between the shearing tool and the substrate (the gap distance in Comparative Example 8 is too large), and the standing time for nucleation (In Comparative Examples 4-5, the standing time for nucleation is too long or too short). As a result, the crystal growth environment has been subject to various disturbances during the crystal growing process. Additionally, the solution evaporation and solute deposition have not been precisely controlled, resulting in an undesirable film morphology. Wherein, the crystal is rugged, the crystal thickness varies a lot, moreover, the crystal orientation is disordered, and many grain boundaries and cracks occur in the crystalline thin film. The performance of the semiconductor device prepared based on the thin film of Comparative Example 4 is shown in Table 5, and the performance is far inferior to the organic single-crystalline thin film semiconductor devices with good morphology. However, in Comparative Examples 5-8, no thin film was obtained at all, only a few solute aggregates showed up, thus the related semiconductor devices could not be produced based on these conditions.

In order to show that the growth-assistant layer needs to choose a suitable range for water contact angle CA_{water}, in Comparative Example 9, a superhydrophobic material was used as the growth-assistant layer, and its water contact angle CA_{water}≥120° is shown in Table 4. Since the solution cannot be well spread on this growth-assistant layer, it is difficult to grow the crystals, therefore the organic semiconductor single-crystalline thin films cannot be obtained. Its morphology is similar to that of FIG. 21, eventually the device cannot be prepared based on this growth-assistant layer.

In Comparative Example 10, organic semiconductor devices were obtained by blending small organic semiconductor molecules with insulating polymers. This kind of organic semiconductor thin film is not single-crystalline, thus the typical phenomenon under cross-polarized light aforementioned for single crystals cannot be observed. The performance of related device is shown in Table 5. However, due to the phase separation, the insulating polymer increases the contact resistance, thereby the obtained organic semiconductor device has poor contact. The relatively poor performance of devices based on blending mixtures further confirms the superiority of the performance of the organic single-crystalline semiconductor device prepared based on the organic semiconductor single-crystalline thin films provided by the present invention.

In Comparative Example 11, the common physical transfer method was used to transfer the organic semiconductor single-crystalline thin films that pre-casted on the silicon wafer to the substrate with pre-deposited source/drain electrode. However, crystals are obtained with imperfections, and most crystals cannot be transferred with the integrity. Since too many steps are involved in the transfer method, the crystals transferred to the substrate also suffer from damage and contamination. There are many cracks on the crystal surface when the peeling off it, and it is impossible to obtain an organic single-crystalline semiconductor thin film with uniform growth crossing the electrodes, moreover, the organic single-crystalline semiconductor thin film obtained is too small to fabricate devices with excellent performance. As shown in Table 5, the hole mobility of the device prepared in Comparative Example 11 is only 0.02 cm² V⁻¹ s⁻¹, which decreases at least an order of magnitude compared with the device in Example 1. The threshold voltage is −39V, and the high absolute value of the threshold voltage proves the poor contact between the crystals and the electrodes, which will result in serious impact on the injection and extraction of carriers. And during the performance characterization, it was observed that many electrodes in the devices are completely unable to work normally, therefore the electrical performance of some devices cannot be obtained. Thus, the advantages of the in-situ growth of the organic semiconductor single crystal array provided by the present invention are further confirmed through the comparison.

Through the Comparative Examples 1-11, it can be concluded that in order to realize the preparation of ideal organic single-crystalline semiconductor devices, it is necessary to achieve the in-situ uniform growth of the organic single-crystalline semiconductor thin films crossing the electrodes on the substrate with the bottom contact structure, that is, the device must meet four requirements at the same time as follows: (1) sequentially deposit growth-assistant layer, electrodes, and organic single-crystalline semiconductor layer from bottom to top on the substrate; (2) the organic single-crystalline semiconductor layer is in-situ grown on the growth-assistant layer and electrodes and is also in contact with them; (3) the organic single-crystalline semiconductor layer is an in-situ uniformly grown organic semiconductor single-crystalline thin film crossing the electrodes; (4) the electrodes contact with the growth-assistant layer with protruding outside of the growth-assistant layer. The electrodes are in contact with the growth-assistant layer in an upper type and/or embedded type, the upper type refers to the upper surface of growth-assistant layer in contact with the lower surface of the electrodes, and the embedded type refers to the electrodes half-embedding or penetrating the growth-assistant layer. The four conditions described are synergistic as a whole and work together to achieve the purpose of the present invention.

TABLE 1
Formulations and process parameters A of Examples 1-24 and Comparative Examples
1-11 (substrate, growth-assistant layer, organic semiconductor material,
solvent, shearing temperature and the linear velocity in the solution shearing)

| | | | Organic | | | linear |
|---|---|---|---|---|---|---|
| | | Growth- | semi- | | | velocity in the |
| | | assistant | conductor | | shearing | solution |
| No. | Substrate | layer | material | Solvent | temperature | shearing |
| Example 1 | SiO₂ | crosslinked | TIPS- | mesitylene | 60° C. | 400 ± 5 μm/s |
| | | polystyrene | pentacene | | | |
| Example 2 | SiO₂ | crosslinked | TIPS- | mesitylene | 80° C. | 400 ± 5 μm/s |
| | | polystyrene | pentacene | | | |
| Example 3 | SiO₂ | crosslinked | TIPS- | mesitylene | 40° C. | 400 ± 5 μm/s |
| | | polystyrene | pentacene | | | |
| Example 4 | SiO₂ | crosslinked | TIPS- | mesitylene | 60° C. | 600 ± 5 μm/s |
| | | polystyrene | pentacene | | | |
| Example 5 | SiO₂ | crosslinked | TIPS- | mesitylene | 60° C. | 200 ± 5 μm/s |
| | | polystyrene | pentacene | | | |
| Example 6 | SiO₂ | Crosslinked | TIPS- | mesitylene: | 60° C. | 200 ± 5 μm/s |
| | | polymethacrylate | pentacene | dodecane = 1:1 | | |
| Example 7 | PEN | crosslinked | TIPS- | mesitylene | 60° C. | 400 ± 5 μm/s |
| | | polystyrene | pentacene | | | |
| Example 8 | SiO₂ | polyimide | Rubrene | 1-chloro- | 200° C. | 10 ± 1 μm/s |
| | | | | naphthalene | | |
| Example 9 | SiO₂ | crosslinked | TIPS- | chloroform | 0° C. | 1 ± 0.1 μm/s |
| | | polystyrene | pentacene | | | |
| Example 10 | SiO₂ | crosslinked | C₈-BTBT | toluene | 100° C. | 10000 ± 20 μm/s |
| | | polystyrene | | | | |
| Example 11 | SiO₂ | polyvinyl | TIPS- | toluene | 60° C. | 400 ± 10 μm/s |
| | | alcohol | pentacene | | | |
| Example 12 | SiO₂ | polyvinyl- | C₈-BTBT | dodecane | 80° C. | 1000 ± 10 μm/s |
| | | pyrrolidone | | | | |
| Example 13 | SiO₂ | hexamethyl- | C₈-BTBT | hexane | 20° C. | 50 ± 1 μm/s |
| | | disilazane | | | | |
| Example 14 | SiO₂ | octadecyl | C₈-BTBT | heptane | 30° C. | 500 ± 10 μm/s |
| | | trichlorosilane | | | | |
| Example 15 | SiO₂ | polyimide | C₈-BTBT | trichlorobenzene | 150° C. | 2000 ± 10 μm/s |
| Example 16 | SiO₂ | benzocyclobutene | C₈-BTBT | m-xylene: | 60° C. | 1000 ± 10 μm/s |
| | | | | dodecane = 2:1 | | |
| Example 17 | SiO₂ | 6-phenyl- | TIPS- | toluene | 60° C. | 200 ± 10 μm/s |
| | | hexyltrichlorosilane | pentacene | | | |
| Example 18 | SiO₂ | polyethersulfone | TIPS- | dodecane | 80° C. | 800 ± 10 μm/s |
| | | | pentacene | | | |
| Example 19 | SiO₂ | polymer based on | diF-TES- | chlorobenzene | 100° C. | 1000 ± 10 μm/s |
| | | perfluoroalkyl | ADT | | | |
| | | vinyl ether | | | | |
| Example 20 | SiO₂ | 1:1 blend of | diF-TES- | toluene | 40° C. | 800 ± 10 μm/s |
| | | polyvinyl | ADT | | | |
| | | alcohol and | | | | |
| | | polyvinylidene | | | | |
| | | fluoride | | | | |
| Example 21 | SiO₂ | 1:1 blend of | diF-TES- | dodecane | 80° C. | 950 ± 10 μm/s |
| | | polystyrene and | ADT | | | |
| | | polymethyl | | | | |
| | | methacrylate | | | | |
| Example 22 | AlOx | octadecyl- | Perylene | toluene | 60° C. | 400 ± 10 μm/s |
| | | phosphonic acid | | | | |
| Example 23 | PI | 6-phenyl- | 9,10-DPA | mesitylene | 60° C. | 400 ± 10 μm/s |
| | | hexyltrichlorosilane | | | | |
| | | is deposited on | | | | |
| | | polymethyl | | | | |
| | | methacrylate | | | | |
| Example 24 | PET | polyvinyl | Perylene | toluene:hexane = | 60° C. | 100 ± 10 μm/s |
| | | alcohol | | 1:1 | | |
| Comparative | PEN | N/A | TIPS- | mesitylene | 60° C. | 400 ± 10 μm/s |
| Example 1 | | | pentacene | | | |
| Comparative | SiO₂ | crosslinked | TIPS- | mesitylene | 60° C. | N/A |
| Example 2 | | polystyrene | pentacene | | | |
| Comparative | SiO₂ | crosslinked | TIPS- | mesitylene | 60° C. | 400 ± 10 μm/s |
| Example 3 | | polystyrene | pentacene | | | |
| Comparative | SiO₂ | crosslinked | TIPS- | mesitylene | 60° C. | 400 ± 10 μm/s |
| Example 3 | | polystyrene | pentacene | | | |
| Comparative | SiO₂ | crosslinked | TIPS- | mesitylene | 60° C. | 400 ± 50 μm/s |
| Example 4 | | polystyrene | pentacene | | | |
| Comparative | SiO₂ | crosslinked | TIPS- | mesitylene | 60° C. | 400 ± 10 μm/s |
| Example 5 | | polystyrene | pentacene | | | |
| Comparative | SiO₂ | crosslinked | TIPS- | mesitylene | 60° C. | 400 ± 10 μm/s |
| Example 6 | | polystyrene | pentacene | | | |
| Comparative | SiO₂ | crosslinked | TIPS- | mesitylene | 60° C. | 400 ± 10 μm/s |
| Example 7 | | polystyrene | pentacene | | | |
| Comparative | SiO₂ | crosslinked | TIPS- | mesitylene | 60° C. | 400 ± 10 μm/s |
| Example 8 | | polystyrene | pentacene | | | |
| Comparative | SiO₂ | Teflon ™ | TIPS- | mesitylene | 60° C. | 400 ± 10 μm/s |
| Example 9 | | AF1600X (AF) | pentacene | | | |
| Comparative | SiO₂ | N/A | TIPS- | mesitylene | 60° C. | 400 ± 10 μm/s |
| Example 10 | | | pentacene | | | |
| Comparative | SiO₂ | N/A | TIPS- | mesitylene | 40° C. | N/A |
| Example 11 | | | pentacene | | | |

**The actual process parameters (including the shearing temperature and the linear velocity in the solution shearing) are allowed to have a deviation of ±2% from the parameters listed in the table.

TABLE 2
Formulations and process parameters B of Examples 1-24 and Comparative
Examples 1-11 (standing time, ambient temperature, ambient humidity, gap
distance, and contact type of electrode and growth-assistant layer)

| | Standing | Ambient | Ambient | Gap | Contact type of electrode and |
|---|---|---|---|---|---|
| No. | time | temperature | humidity | distance | growth-assistant layer |
| Example 1 | 10 s | 20 ± 1° C. | 40 ± 2% | 150 μm | upper type |
| Example 2 | 5 s | 20 ± 1° C. | 50 ± 2% | 150 μm | upper type |
| Example 3 | 15 s | 20 ± 1° C. | 40 ± 2% | 150 μm | embedded type |
| Example 4 | 10 s | 25 ± 1° C. | 40 ± 2% | 100 μm | embedded type |
| Example 5 | 2 s | 25 ± 1° C. | 40 ± 2% | 50 μm | embedded type |
| Example 6 | 10 s | 25 ± 1° C. | 50 ± 2% | 150 μm | random arrangement of upper |
| | | | | | type and embedded type |
| Example 7 | 15 s | 25 ± 1° C. | 50 ± 2% | 300 μm | upper type |
| Example 8 | 1 s | 20 ± 1° C. | 50 ± 2% | 300 μm | upper type |
| Example 9 | 5 s | 20 ± 1° C. | 30 ± 2% | 275 μm | upper type |
| Example 10 | 30 s | 20 ± 1° C. | 30 ± 2% | 250 μm | random arrangement of upper |
| | | | | | type and embedded type |
| Example 11 | 15 s | 20 ± 1° C. | 50 ± 2% | 300 μm | upper type |
| Example 12 | 20 s | 25 ± 1° C. | 30 ± 2% | 250 μm | upper type |
| Example 13 | 15 s | 25 ± 1° C. | 55 ± 3% | 100 μm | upper type |
| Example 14 | 25 s | 20 ± 1° C. | 30 ± 2% | 150 μm | upper type |
| Example 15 | 5 s | 25 ± 2° C. | 40 ± 3% | 300 μm | upper type |
| Example 16 | 10 s | 20 ± 1° C. | 40 ± 2% | 50 μm | embedded type |
| Example 17 | 10 s | 20 ± 1° C. | 40 ± 2% | 250 μm | upper type |
| Example 18 | 10 s | 20 ± 1° C. | 40 ± 2% | 250 μm | upper type |
| Example 19 | 10 s | 20 ± 1° C. | 40 ± 2% | 250 μm | upper type |
| Example 20 | 5 s | 20 ± 1° C. | 40 ± 2% | 200 μm | embedded type |
| Example 21 | 5 s | 25 ± 1° C. | 40 ± 2% | 270 μm | embedded type |
| Example 22 | 5 s | 20 ± 1° C. | 40 ± 2% | 200 μm | embedded type |
| Example 23 | 10 s | 20 ± 1° C. | 40 ± 2% | 200 μm | embedded type |
| Example 24 | 10 s | 20 ± 1° C. | 40 ± 2% | 300 μm | embedded type |
| Comparative | 15 s | 25 ± 1° C. | 50 ± 2% | 300 μm | upper type |
| Example 1 | | | | | |
| Comparative | N/A | 25 ± 1° C. | 50 ± 2% | N/A | upper type |
| Example 2 | | | | | |
| Comparative | 5 s | 20 ± 1° C. | 50 ± 2% | 150 μm | N/A |
| Example 3 | | | | | |
| Comparative | 60 s | 20 ± 3° C. | 50 ± 2% | 200 μm | upper type |
| Example 4 | | | | | |
| Comparative | 0 s | 25 ± 2° C. | 50 ± 3% | 200 μm | upper type |
| Example 5 | | | | | |
| Comparative | 10 s | 25 ± 2° C. | 80 ± 5% | 200 μm | upper type |
| Example 6 | | | | | |
| Comparative | 10 s | 30 ± 3° C. | 50 ± 2% | 200 μm | upper type |
| Example 7 | | | | | |
| Comparative | 10 s | 25 ± 1° C. | 50 ± 2% | 1000 μm | embedded type |
| Example 8 | | | | | |
| Comparative | 10 s | 25 ± 1° C. | 50 ± 2% | 250 μm | upper type |
| Example 9 | | | | | |
| Comparative | 5 s | 25 ± 1° C. | 40 ± 2% | 250 μm | upper type |
| Example 10 | | | | | |
| Comparative | N/A | 25 ± 2° C. | 50 ± 2% | N/A | N/A |
| Example 11 | | | | | |

** The actual process parameters (including the standing time, ambient temperature, ambient humidity, and gap distance) are allowed to have a deviation of ± 2% from the parameters listed in the table.

Table 3
Morphology parameters of the organic single-crystalline semiconductor
structures of Examples 1-24 and Comparative Examples 2-4

| | | | | morphology of the | | |
|---|---|---|---|---|---|---|
| No. | f_{cr} | f_{cp} | F | linear element | b | g |
| Example 1 | 100% | 79.88% | 0.997 | p1D(c/a > 500, | 12.45 nm ± 0.24 nm | 0.72 μm |
| | | | | c/b > 500) | | |
| Example 2 | 100% | 64.23% | 0.993 | p1D (c/a > 500, | 23.36 nm ± 0.58 nm | 0.45 μm |
| | | | | c/b > 500) | | |
| Example 3 | 100% | 73.15% | 0.989 | p1D (c/a > 1000, | 17.10 nm ± 0.23 nm | 0.81 μm |
| | | | | c/b > 1000) | | |
| Example 4 | 100% | 83.42% | 0.830 | p1D (c/a > 500, | 45.76 nm ± 4.09 nm | 3.77 μm |
| | | | | c/b > 500) | | |
| Example 5 | 100% | 69.64% | 0.878 | p1D (c/a > 1000, | 40.68 nm ± 7.76 nm | 6.12 μm |
| | | | | c/b > 1000) | | |
| Example 6 | 100% | 67.62% | 0.851 | p1D(c/a > 500, | 20.37 nm ± 2.53 nm | 4.14 μm |
| | | | | c/b > 500) | | |
| Example 7 | 100% | 84.13% | 0.986 | p1D (c/a > 2000, | 42.56 nm ± 8.20 nm | 10.56 μm |
| | | | | c/b > 2000) | | |
| Example 8 | 94.12% | 54.27% | 0.986 | p1D (c/a > 500, | 398.21 nm ± 52.11 nm | 14.35 μm |
| | | | | c/b > 500) | | |
| Example 9 | 88.50% | 68.98% | 0.994 | p1D (c/a > 500, | 201.47 nm ± 35.93 nm | 17.88 μm |
| | | | | c/b > 500) | | |
| Example 10 | 84.36% | 73.10% | 0.924 | p2D (a/b > 1000, | 58.17 nm ± 12.31 nm | 11.85 μm |
| | | | | c/b > 1000) | | |
| Example 11 | 89.35% | 66.63% | 0.941 | p1D (c/a > 500, | 47.08 nm ± 9.74 nm | 6.34 μm |
| | | | | c/b > 500) | | |
| Example 12 | 97.81% | 80.07% | 0.950 | p2D (a/b > 500, | 54.86 nm ± 2.44 nm | 7.09 μm |
| | | | | c/b > 500) | | |
| Example 13 | 80.21% | 51.36% | 0.627 | p2D (a/b > 500, | 67.89 nm ± 25.11 nm | 25.80 μm |
| | | | | c/b > 500) | | |
| Example 14 | 90.35% | 82.17% | 0.793 | p1D (c/a > 500, | 36.75 nm ± 6.12 nm | 4.43 μm |
| | | | | c/b > 500) | | |
| Example 15 | 83.58% | 100% | 1 | p2D (a/b > 2000, | 57.21 nm ± 18.64 nm | 0 μm |
| | | | | c/b > 2000) | | |
| Example 16 | 95.71% | 56.90% | 0.878 | p1D (c/a > 500, | 2.37 nm ± 0.89 nm | 5.32 μm |
| | | | | c/b > 500) | | |
| Example 17 | 92.19% | 50.48% | 0.913 | p1D (c/a > 500, | 17.21 nm ± 6.56 nm | 12.39 μm |
| | | | | c/b > 500) | | |
| Example 18 | 84.06% | 80.12% | 0.925 | p1D (c/a > 500, | 36.75 nm ± 6.12 nm | 4.43 μm |
| | | | | c/b > 500) | | |
| Example 19 | 86.58% | 79.94% | 0.967 | p1D (c/a > 500, | 5.37 nm ± 2.44 nm | 0.86 μm |
| | | | | c/b > 500) | | |
| Example 20 | 99.82% | 83.26% | 0.948 | p1D (c/a > 500, | 22.46 nm ± 4.85 nm | 3.47 μm |
| | | | | c/b > 500) | | |
| Example 21 | 86.58% | 79.94% | 0.899 | p2D (a/b > 500, | 17.46 nm ± 2.08 nm | 3.90 μm |
| | | | | c/b > 500) | | |
| Example 22 | 94.62% | 51.70% | 0.857 | p1D (c/a > 500, | 74.73 nm ± 15.75 nm | 6.52 μm |
| | | | | c/b > 500) | | |
| Example 23 | 100% | 58.19% | 0.974 | p1D (c/a > 500, | 9.20 nm ± 1.48 nm | 1.15 μm |
| | | | | c/b > 500) | | |
| Example 24 | 87.66% | 50.47% | 0.962 | p1D (c/a > 500, | 150.82 nm ± 35.34 nm | 989.30~ |
| | | | | c/b > 500) | | 995.68 μm |
| Comparative | 68.74% | 44.29% | 0.675 | p1D (c/a > 500, | 157.66 nm ± 62.71 nm | 14.19 μm |
| Example 2 | | | | c/b > 500) | | |
| Comparative | 94.36% | 78.68% | 0.996 | p1D (c/a > 500, | 19.21 nm ± 3.84 nm | 0.77 μm |
| Example 3 | | | | c/b > 500 | | |
| Comparative | 73.43% | 51.95% | 0.571 | N/A | 189.52 nm ± 121.44 nm | 4.38~ |
| Example 4 | | | | | | 36.72 μm |

**Actually obtained crystal morphology parameters (including effective coverage fcr in the lengthwise direction, effective coverage f_{cp} in the vertical direction, c/a, c/b, a/b, degree of orientation F, thickness b, and gap g) are allowed ±3% deviation from the tested parameters listed in the table.

TABLE 4
CA_{water} of the contact angle between the growth-assistant layer and water in
Examples 1-24 and Comparative Examples 1-10

| growth- | | | | |
|---|---|---|---|---|
| assistant | crosslinked | crosslinked | | |
| layer | polystyrene | polymethacrylate | polyimide | polyvinyl alcohol |
| CA_{water} | ~107° | ~68° | ~80° | ~36° |
| growth- | polyethersulfone | polymer based on | 1:1 blend of | 1:1 blend of |
| assistant | | perfluoroalkyl vinyl ether | polyvinyl alcohol | polystyrene and |
| layer | | | and polyvinylidene | polymethyl |
| | | | fluoride | methacrylate |
| CA_{water} | ~78° | ~120° | ~70° | ~76° |
| growth- | hexamethyldisilazane | 6-phenylhexyl | octadecyl | Teflon ™ AF1600X |
| assistant | | trichlorosilane | trichlorosilane | (AF) |
| layer | | | | |
| CA_{water} | −60° | ~90° | ~100° | >120° |
| growth- | polyvinylpyrrolidone | octadecylphosphonic acid | | |
| assistant | | | | |
| layer | | | | |
| CA_{water} | ~30° | ~117° | | |

**The actual parameter of CA_{water} and the tested parameters listed in the table are allowed to have a deviation of ±3%.

TABLE 5
Performance statistics of saturation region mobilities and
threshold voltages of the organic single-crystalline field-
effect transistors at V_{DS} = −60 V, V_{G} = −60 V obtained in Examples
1-5, Example 7, Example 10, Example 19 and Comparative
Examples 3-4, Comparative Examples 10-11.

| No. | Hole mobility | Threshold voltage |
|---|---|---|
| Example 1 | 0.87 cm² V⁻¹s⁻¹ | −9 V |
| Example 2 | 0.64 cm² V⁻¹s⁻¹ | −10 V |
| Example 3 | 0.58 cm² V⁻¹s⁻¹ | −16 V |
| Example 4 | 1.04 cm² V⁻¹s⁻¹ | −12 V |
| Example 5 | 0.68 cm² V⁻¹s⁻¹ | −5 V |
| Example 7 | 1.49 cm² V⁻¹s⁻¹ | −11 V |
| Example 10 | 0.92 cm² V⁻¹s⁻¹ | −15 V |
| Example 19 | 0.61 cm² V⁻¹s⁻¹ | −10 V |
| Comparative Example 3 | 0.11 cm² V⁻¹s⁻¹ | −36 V |
| Comparative Example 4 | 0.12 cm² V⁻¹s⁻¹ | −30 V |
| Comparative Example 10 | 0.42 cm² V⁻¹s⁻¹ | −27 V |
| Comparative Example 11 | 0.02 cm² V⁻¹s⁻¹ | −39 V |

What is claimed is:

1. An organic single-crystalline semiconductor structure, comprising a substrate, a growth-assistant layer, electrodes and an organic single-crystalline semiconductor layer; wherein the last three are deposited sequentially from bottom to top on the substrate;
the organic single crystal semiconductor layer is grown on the growth-assistant layer and the electrodes, the organic semiconductor layer is composed of organic single-crystalline semiconductor thin film, and the organic single-crystalline semiconductor thin film is constructed by organic semiconductor single crystal arrays; the morphology of organic semiconductor single crystal array keeps basically unchanged before crossing the electrode (100), at the electrode edges (101 and 103), on the electrode (102), and after crossing the electrode (104).

2. The organic single-crystalline semiconductor structure of claim 1, wherein he organic single-crystalline semiconductor thin film can realize complete/full coverage on a substrate of arbitrary shape or arbitrary size.

3. The organic single-crystalline semiconductor structure of claim 1, wherein the organic single-crystalline semiconductor thin films have an effective coverage ratio f_{cr}≥80% in the lengthwise direction of the crystals, and an effective coverage ratio f_{cp}≥50% in the vertical direction of the crystals.

4. The organic single-crystalline semiconductor structure of claim 3, wherein the lengthwise directional effective coverage ratio f_{cr}=(c_{L1}+c_{L2}+ . . . +c_{Lm})/(L₁+L₂+ . . . +Lₘ), wherein m is a positive integer greater than or equal to 5, c_{L1}, c_{L2}, . . . , c_{Lm} represent continuous lengths of crystals c_{L} in the 1, 2, . . . , m channels in m adjacent and continuous channels, respectively; and L₁, L₂, . . . , Lₘ represent the lengths L of the 1, 2, . . . , m channels covered by crystals, respectively; for the vertical directional effective coverage ratio, fcp=(k₁+k₂+ . . . +kₙ)/W, k₁, k₂, . . . , kₙ represent the contact widths k between the 1, 2, . . . , n crystals and source/drain electrodes, respectively, W represents width of channel, wherein n is a positive integer greater than or equal to 8.

5. The organic single-crystalline semiconductor structure of claim 1, wherein the electrodes contact with the growth-assistant layer with protruding outside of the growth-assistant layer; the electrodes are in contact with the growth-assistant layer in an upper type and/or embedded type, the upper type refers to the upper surface of growth-assistant layer in contact with the lower surface of the electrodes, and the embedded type refers to the electrodes half-embedding or penetrating the growth-assistant layer.

6. The organic single-crystalline semiconductor structure of claim 1, wherein the organic single-crystalline semiconductor thin films are well-aligned organic semiconductor single crystal arrays, which is composed of multiple separate and independent linear-type elements; the multiple linear elements are arranged in a linear-type arrangement, and the linear-type arrangement refers to the well-aligned orientation/arrangement of the linear elements along the crystal growth direction; the morphology of linear elements keep basically unchanged before crossing the electrode (100), at the electrode edges (101 and 103), on the electrode (102), and after crossing the electrode (104); the linear element is an independent crystal with single-crystalline morphology.

7. The organic single-crystalline semiconductor structure of claim 6, wherein the well-aligned orientation/arrangement refers to the degree of orientation F≥0.625.

8. The organic single-crystalline semiconductor structure of claim 7, wherein the detection method of F is: randomly selecting n linear elements of the organic single-crystalline semiconductor thin film as samples, wherein n is a positive integer greater than or equal to 10; the crystal growth direction is taken as the reference direction; take the angle between the direction of the longest dimension c of each linear element and the reference direction as the orientation angle A, the average value of the orientation angles of the n linear elements as Ā; the degree of orientation F=0.5*(3*cos² Ā−1).

9. The organic single-crystalline semiconductor structure of claim 6, wherein the morphology of the linear element is pseudo one-dimensional (pseudo 1D, p1D) or pseudo two-dimensional (pseudo 2D, p2D); when the length c of a single crystal along the crystal growth direction is much larger than the width a of the crystal and the thickness b of the crystal, that is, when c/a≥500 and c/b≥500, the morphology is p1D.

10. The organic single-crystalline semiconductor structure of claim 6, wherein the top view of linear element is linear or facial form in the stereogram, and the thickness b of linear element is 2 nm to 400 nm.

11. The organic single-crystalline semiconductor structure of claim 6, wherein the thickness of linear element is highly uniform.

12. The organic single-crystalline semiconductor structure of claim 6, wherein the detection method of “the thickness of linear element is highly uniform” is: randomly taking p samples of linear elements in the organic single-crystalline semiconductor thin film and characterizing the thickness b of the linear elements, the average thickness of p linear elements is b̅, and p is a positive integer greater than or equal to 8, when b̅<10 nm, the coefficient of variation of the thickness of the linear element in p samples is ≤40%, when 10 nm≤b≤50 nm, the coefficient of variation of the thickness of the linear element in p samples is ≤30%, when b̅≥50 nm, the coefficient of variation of the thickness of the linear element in p samples is ≤20%, indicating that linear elements have highly uniform thickness; preferably, when b̅<10 nm, the coefficient of variation of the thickness of the linear element in p samples is ≤30%, when 10 nm≤b̅≤50 nm, the coefficient of variation of the thickness of the linear element in p samples is ≤20%, when b̅≥50 nm, the coefficient of variation of the thickness of the linear element in p samples is ≤10%.

13. The organic single-crystalline semiconductor structure of claim 6, wherein the gap width g of each of the linear elements along the crystal growth direction is 0 mm to 1 mm; preferably, the gap width g≤10 μm.

14. The organic single-crystalline semiconductor structure of claim 1, wherein the growth-assistant layer is an organic insulating thin film.

15. The organic single-crystalline semiconductor structure of claim 14, wherein the water contact angle CA_{water} that between the organic insulating thin film and water is 30° to 120°.

16. The organic single-crystalline semiconductor structure of claim 14, wherein the material of the organic insulating film has π-conjugated system, and the π-conjugated system refers to a system wherein conjugated π bonds are able to form.

17. The organic single-crystalline semiconductor structure of claim 14, wherein the material of organic insulating film is selected from any one or more from the group consisting of self-assembled small molecules containing silyl groups, self-assembled small molecules containing phosphate groups, self-assembled small molecules containing thiol groups, dielectric polymers.

18. The organic single-crystalline semiconductor structure of claim 1, wherein the core of the material of the organic single-crystalline semiconductor thin film contains a conjugated structure, with a band gap width ≤3.5 eV.

19. The organic single-crystalline semiconductor structure of claim 1, wherein the organic semiconductor single crystal array is obtained by in-situ uniform growth crossing the electrodes.

20. A field-effect transistor, comprising:
the organic single-crystalline semiconductor structure of claim 1; the field-effect transistor includes top-gate and bottom-gate devices; the gate and dielectric layer of the top-gate devices are located above the organic single-crystalline semiconductor structure; the gate and dielectric layer of the bottom-gate devices are located beneath the organic single-crystalline semiconductor structure.

21. A preparation method of the organic single-crystalline semiconductor structure, comprising:
(1) sequentially preparing the growth-assistant layer and the electrodes on the substrate; preferably, the electrodes are in contact with the growth-assistant layer in an upper type and/or embedded type; the upper type means that the upper surface of the growth-assistant layer is in contact with the lower surface of the electrodes, and the embedded type means that the electrode is half-embed or penetrates the growth-assistant layer;
(2) dissolving the organic semiconductor material in an organic solvent to prepare an organic semiconductor solution;
(3) regulating the temperature and humidity of the growth environment to obtain a stable growth environment, the deviation of the ambient temperature is ≤±2° C., and the deviation of the ambient humidity is ≤±3%;
(4) adjusting the gap distance between the shearing tool and the substrate that prepared in step (1), the gap distance is 50 μm to 300 μm; guaranteeing the deviation of the gap distance that between the lower surface of the shearing tool and the substrate ≤10 μm in order to obtain a stable storage space for solution; the solution storage space is the space formed between the lower surface of the shearing tool and the substrate;
(5) filling the organic semiconductor solution prepared in step (2) into the solution storage space prepared in step (4), and let it stand for 1 to 30 seconds after the filling is completed;
(6) shearing the organic semiconductor solution at a constant linear velocity under a constant shearing temperature in a constant direction from (100) to (104) to achieve organic single-crystalline semiconductor thin film on the substrates, wherein (100) represents before crossing the electrodes and (104) represents after crossing the electrodes; the organic single-crystalline semiconductor thin film is composed of organic semiconductor single crystal arrays, and the morphology of organic semiconductor single crystal array keeps basically unchanged before crossing the electrode (100), at the electrode edges (101 and 103), on the electrode (102), and after crossing the electrode (104); the constant shearing temperature refers to the temperature deviation ≤±1° C. in the space including the substrate and the solution storage space; the constant linear velocity refers to the deviation of the linear velocity ≤±20 μm/s.

22. The preparation method of claim 21, wherein the step of further treatment for the organic single-crystalline semiconductor thin films after step (6) are also included.
